(19) United States
(12) Patent Application Publication
(10) Pub. No.: US 2024/0251644 A1
(43) Pub. Date: Jul. 25, 2024

(54) DISPLAY APPARATUS

(71) Applicant: LG Display Co., Ltd., Seoul (KR)

(72) Inventors: SeHong PARK, Paju-si (KR); Wonrae KIM, Paju-si (KR); Inae CHOI, Paju-si (KR); Sejong SEONG, Paju-si (KR); SeoHyun NAM, Paju-si (KR)

(21) Appl. No.: 18/510,170

(22) Filed: Nov. 15, 2023

(30) Foreign Application Priority Data
Jan. 20, 2023 (KR) 10-2023-0008715

(51) Int. Cl. H10K 59/80; H10K 59/122; H10K 59/35

(52) U.S. Cl. CPC H10K 59/879; H10K 59/122; H10K 59/351; H10K 59/80518; H10K 59/878

(57) ABSTRACT

A display apparatus is provided, which may improve light extraction efficiency of light emitted from a light emitting element layer. The display apparatus comprises a substrate having a plurality of pixels having a plurality of subpixels, a pattern portion disposed on the substrate and formed to be concave between the plurality of subpixels, and a reflective portion on the pattern portion, wherein the plurality of subpixels include an overcoat layer having a first layer on the substrate and a light extraction portion adjacent to the reflective portion, having a plurality of concave portions formed on the first layer, an optimal radius R_{BEST} of the concave portion satisfies R_{BEST}=0.15 sin 4π(AR+0.05)+1.5n_{oc}+0.5m−0.59, wherein ‘π’ is a circumferential rate, AR is an aspect ratio of the concave portion, ‘n_{oc}’ is a refractive index of the first layer, and ‘m’ is a variable value according to a process of forming the plurality of concave portions.

### CROSS-REFERENCE TO RELATED APPLICATION

This application claims the benefit of the Korean Patent Application No. 10-2023-0008715 filed on Jan. 20, 2023, which is hereby incorporated by reference as if fully set forth herein.

### BACKGROUND

### Technical Field

The present disclosure relates to a display apparatus for displaying an image.

### Description of the Related Art

Since an organic light emitting display apparatus has a high response speed and low power consumption, does not require a separate light source unlike a liquid crystal display apparatus, and self-emits light to be individually driven for each pixel, the organic light emitting display apparatus may implement perfect black and thus the organic light emitting display apparatus has received attention as a next-generation flat panel display apparatus.

Such a display apparatus displays an image through light emission of a light emitting element layer that includes a light emitting layer interposed between two electrodes.

Meanwhile, light extraction efficiency of the display apparatus is reduced as some of light emitted from the light emitting element layer is not emitted to the outside due to total reflection on the interface between the light emitting element layer and an electrode and/or between a substrate and an air layer.

### BRIEF SUMMARY

The present disclosure provides a display apparatus that improv light extraction efficiency of light emitted from a light emitting element layer.

The present disclosure provides a display apparatus that improves light extraction efficiency.

The present disclosure provides a display apparatus in which light extraction efficiency may be further improved through light extraction from a non-light emission area.

The present disclosure provides a display apparatus that may reduce power consumption.

In addition to the technical features of the present disclosure as mentioned above, additional technical benefits and features of the present disclosure will be clearly understood by those skilled in the art from the following description of the present disclosure.

In accordance with an aspect of the present disclosure, the above and other technical achievements can be accomplished by the provision of a display apparatus comprising a substrate having a plurality of pixels having a plurality of subpixels, a pattern portion disposed on the substrate and formed to be concave between the plurality of subpixels, and a reflective portion on the pattern portion, wherein the plurality of subpixels include an overcoat layer having a first layer on the substrate and a light extraction portion adjacent to the reflective portion, having a plurality of concave portions formed on the first layer, an optimal radius R_{BEST} of the concave portion satisfies R_{BEST}=0.15 sin 4π(AR+0.05)+1.5n_{oc}+0.5m−0.59, wherein ‘π’ is a circumferential rate, AR is an aspect ratio of the concave portion, ‘n_{oc}’ is a refractive index of the first layer, and ‘m’ is a variable value according to a process of forming the plurality of concave portions.

In accordance with another aspect of the present disclosure, the above and other technical achievements can be accomplished by the provision of a display apparatus comprising a substrate having a plurality of pixels having a plurality of subpixels, a pattern portion disposed on the substrate and formed to be concave between the plurality of subpixels, and a reflective portion on the pattern portion, wherein the plurality of subpixels include an overcoat layer having a first layer on the substrate and a light extraction portion adjacent to the reflective portion, having a plurality of concave portions formed on the first layer, and an optimal radius of the concave portion is proportional to a refractive index of the first layer.

### BRIEF DESCRIPTION OF THE SEVERAL VIEWS OF THE DRAWINGS

The above and other objects, features and other advantages of the present disclosure will be more clearly understood from the following detailed description taken in conjunction with the accompanying drawings, in which:

FIG. 1 is a schematic plan view illustrating a display apparatus according to one embodiment of the present disclosure;

FIG. 2 is a schematic plan view illustrating one pixel shown in FIG. 1;

FIG. 3 is a schematic cross-sectional view taken along line I-I′ shown in FIG. 2;

FIG. 4A is a schematic view illustrating a light path of a display apparatus having a light extraction portion according to a comparative example;

FIG. 4B is a schematic view illustrating a light path of a display apparatus according to one embodiment of the present disclosure;

FIG. 5A is a cross-sectional view illustrating an example of a portion A of FIG. 3;

FIG. 5B is a cross-sectional view illustrating another example of a portion A of FIG. 3;

FIG. 6A is a graph illustrating an efficiency increasing rate based on a luminance viewing angle of first extraction light of a display apparatus according to one embodiment of the present disclosure;

FIG. 6B is a graph illustrating an efficiency increasing rate based on a luminance viewing angle of second extraction light of a display apparatus according to one embodiment of the present disclosure;

FIG. 7A is a light efficiency map illustrating light efficiency based on a radius of a concave portion and an aspect ratio of the concave portion in each of subpixels when a difference in refractive index between a first layer and a second layer of a display apparatus according to one embodiment of the present disclosure is 0.16;

FIG. 7B is a light efficiency map illustrating light efficiency based on a radius of a concave portion and an aspect ratio of the concave portion in each of subpixels when a difference in refractive index between a first layer and a second layer of a display apparatus according to one embodiment of the present disclosure is 0.2;

FIG. 8A is a light efficiency map illustrating light efficiency based on a process of forming a concave portion of a white subpixel when a difference in refractive index between a first layer and a second layer of a display apparatus according to one embodiment of the present disclosure is 0.16; and

FIG. 8B is a light efficiency map illustrating light efficiency based on a process of forming a concave portion of a white subpixel when a difference in refractive index between a first layer and a second layer of a display apparatus according to one embodiment of the present disclosure is 0.2.

### DETAILED DESCRIPTION

Reference will now be made in detail to the embodiments of the present disclosure, examples of which are illustrated in the accompanying drawings. Wherever possible, the same reference numbers will be used throughout the drawings to refer to the same or like parts.

Advantages and features of the present disclosure, and implementation methods thereof will be clarified through following embodiments described with reference to the accompanying drawings.

The present disclosure may however, be embodied in different forms and should not be construed as limited to the embodiments set forth herein. Rather, these embodiments are provided so that this disclosure will be thorough and complete, and will fully convey the scope of the present disclosure to those skilled in the art.

A shape, a size, a ratio, an angle, and a number disclosed in the drawings for describing embodiments of the present disclosure are merely an example, and thus, the present disclosure is not limited to the illustrated details.

Like reference numerals refer to like elements throughout. In the following description, when the detailed description of the relevant known function or configuration is determined to unnecessarily obscure the important point of the present disclosure, the detailed description will be omitted.

In a case where ‘comprise.’ ‘have,’ and ‘include’ described in the present specification are used, another part may be added unless ‘only˜’ is used. The terms of a singular form may include plural forms unless referred to the contrary.

In construing an element, the element is construed as including an error range although there is no explicit description. In describing a position relationship, for example, when a position relation between two parts is described as ‘on˜,’ ‘over˜,’ ‘under˜,’ and ‘next˜,’ one or more other parts may be disposed between the two parts unless ‘just’ or ‘direct’ is used.

In describing a temporal relationship, for example, when the temporal order is described as “after,” “subsequent,” “next,” and “before,” a case which is not continuous may be included, unless “just” or “direct” is used.

A “predetermined” value, parameter, threshold, condition or setting can be dynamically determined or adjusted by a machine with or without human inputs. A “predetermined” value, parameter, threshold, condition or setting does not mean or limit to that the value, parameter, threshold, condition or setting is fixed or is input by a human.

It will be understood that, although the terms “first,” “second,” etc., may be used herein to describe various elements, these elements should not be limited by these terms.

These terms are only used to distinguish one element from another. For example, a first element could be termed a second element, and, similarly, a second element could be termed a first element, without departing from the scope of the present disclosure.

“X-axis direction,” “Y-axis direction” and “Z-axis direction” should not be construed by a geometric relation only of a mutual vertical relation and may have broader directionality within the range that elements of the present disclosure may act functionally.

The term “at least one” should be understood as including any and all combinations of one or more of the associated listed items. For example, the meaning of “at least one of a first item, a second item or a third item” denotes the combination of all items proposed from two or more of the first item, the second item and the third item as well as the first item, the second item or the third item.

Features of various embodiments of the present disclosure may be partially or overall coupled to or combined with each other and may be variously inter-operated with each other and driven technically as those skilled in the art can sufficiently understand. The embodiments of the present disclosure may be carried out independently from each other or may be carried out together in co-dependent relationship.

Hereinafter, the preferred embodiments of the present disclosure will be described in detail with reference to the accompanying drawings.

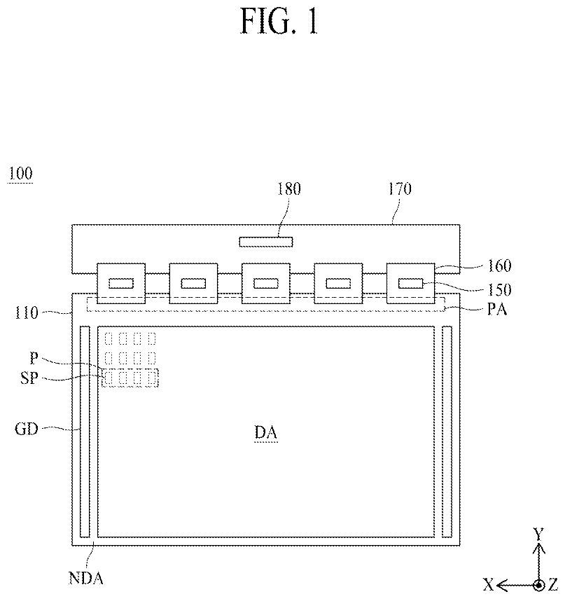

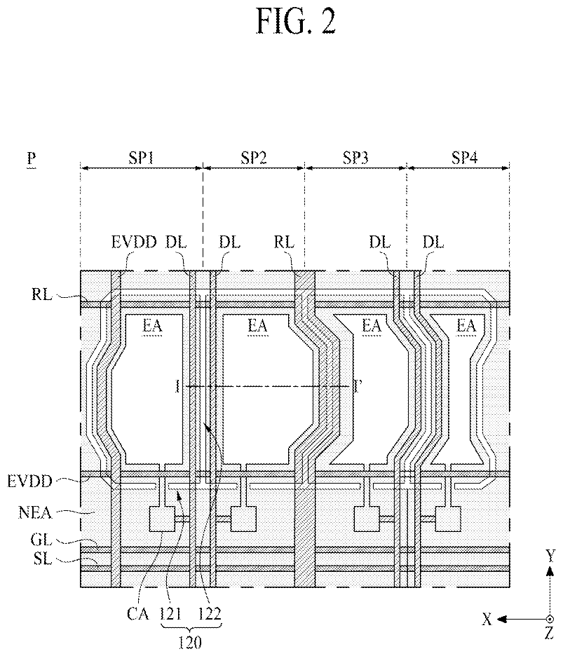

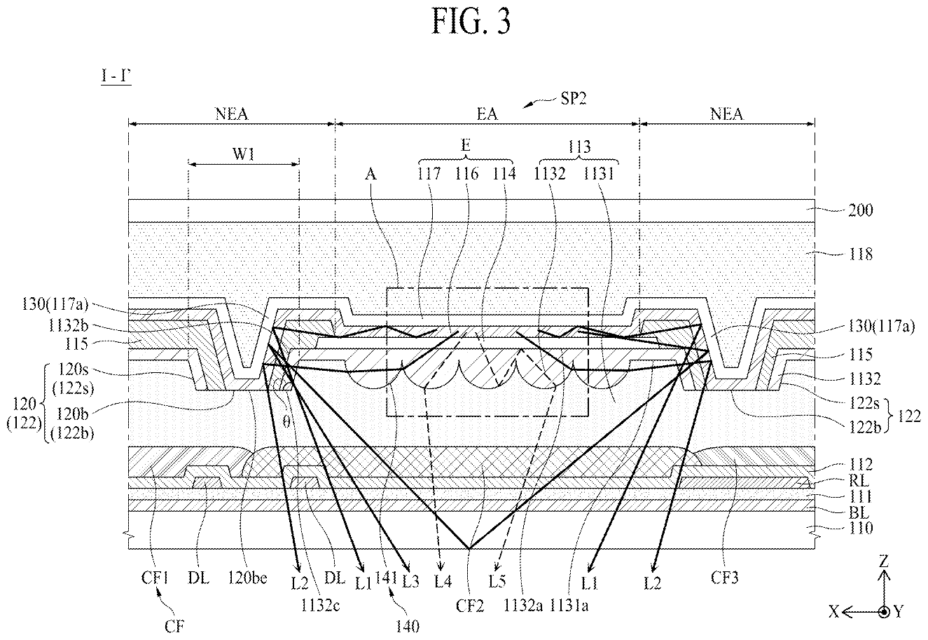

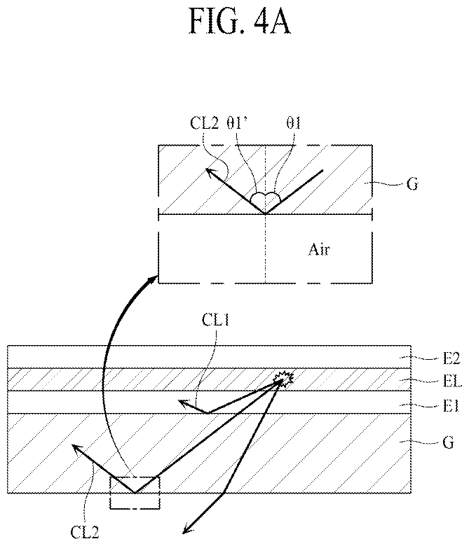

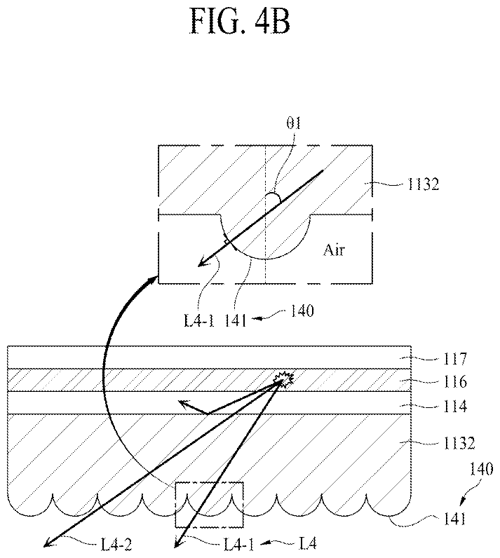

FIG. 1 is a schematic plan view illustrating a display apparatus according to one embodiment of the present disclosure, FIG. 2 is a schematic plan view illustrating one pixel shown in FIG. 1, FIG. 3 is a schematic cross-sectional view taken along line I-I′ shown in FIG. 2, FIG. 4A is a schematic view illustrating a light path of a display apparatus having no a light extraction portion according to a comparative example, and FIG. 4B is a schematic view illustrating a light path of a display apparatus according to one embodiment of the present disclosure.

Referring to FIGS. 1 to 4B, a display apparatus 100 according to one embodiment of the present disclosure includes a substrate 110 having a plurality of pixels P having a plurality of subpixels SP, a pattern portion 120 disposed on the substrate 110 and formed to be concave between the plurality of subpixels SP, and a reflective portion 130 on the pattern portion 120.

The plurality of subpixels SP may include an overcoat layer 113 having a first layer 1131 having a plurality of concave portions 141, and a light extraction portion 140 adjacent to a reflective portion 130, having the plurality of concave portions 141 formed in the first layer 1131.

In this case, an optimal radius R of the concave portion 141 may satisfy R_{BEST}=0.15 sin 4π(AR+0.05)+1.5n_{oc} +0.5m−0.59. ‘π’ is a circumferential rate (or ‘π’ is the ratio of a circle's circumference to its diameter (i.e., π=3.14159 . . . )), AR is an aspect ratio (or a horizontal and vertical ratio) of each of the plurality of concave portions, ‘n_{oc}’ is a refractive index of the first layer 1131, and ‘m’ is a variable value according to a process of forming the plurality of concave portions 141.

The display apparatus 100 according to one embodiment of the present disclosure is provided so that each of the plurality of subpixels SP includes a light extraction portion 140 having a plurality of concave portions 141, whereby light emitted from a light emitting element layer E disposed in the plurality of subpixels SP may be output to a light emission area of the subpixel for emitting light and thus light extraction efficiency may be improved.

Also, the display apparatus 100 according to one embodiment of the present disclosure may be provided so that the optimal radius R_{BEST} of each of the plurality of concave portions 141 is proportional to the refractive index (and/or the aspect ratio of each of the plurality of concave portions) of the first layer 1131. Therefore, in the display apparatus 100 according to one embodiment of the present disclosure, each of the plurality of concave portions 141 included in the light extraction portion 140 is provided in an optimal form satisfying the above equation, whereby front light extraction efficiency of the light emitted from the light emitting element layer E may be increased to maximize light extraction efficiency. In this case, the front light extraction efficiency may include that light emitted from the light emission area EA and directed toward an adjacent subpixel SP is refracted to be output toward the subpixel SP for emitting light. Therefore, the increase in front light extraction efficiency may mean that a luminance viewing angle is reduced. On the contrary, an increase in the luminance viewing angle may mean that the front light extraction efficiency is reduced. That is, the front light extraction efficiency and the luminance viewing angle may have a trade-off relation.

Meanwhile, in the display apparatus 100 according to one embodiment of the present disclosure, the reflective portion 130 is provided on the pattern portion 120 formed to be concave between a plurality of subpixels SP (or in a non-light emission area NEA), so that light extraction may be performed between the plurality of subpixels SP (or in the non-light emission area NEA, whereby overall light efficiency may be improved. Therefore, in the display apparatus 100 according to one embodiment of the present disclosure, light extraction may be performed even in the non-light emission area NEA, and the display apparatus 100 according to one embodiment of the present disclosure may have the same light emission efficiency or more improved light emission efficiency even with low power as compared with a general display apparatus having no reflective portion, whereby overall power consumption may be reduced.

Referring to FIGS. 1 to 4B, each of the plurality of subpixels SP according to one example may include a light emission area EA and a non-light emission area NEA adjacent to the light emission area EA. The light emission area EA is an area from which light is emitted, and may be included in a display area DA. The non-light emission area NEA is an area from which light is not emitted, and may be an area adjacent to the light emission area EA. The non-light emission area NEA may be expressed as a term of a peripheral area.

The pattern portion 120 according to one example may be formed to be concave between the plurality of subpixels SP (or the non-light emission area NEA). For example, the pattern portion 120 may be formed to be concave in an overcoat layer 113 (shown in FIG. 3) on the substrate 110. The pattern portion 120 may be disposed to be spaced apart from the light emission area EA. The pattern portion 120 according to one example may be provided to surround the light emission area EA in the form of a slit or a trench. The pattern portion 120 may be disposed to be spaced apart from the light emission area EA. For example, a width (only one width W1 is shown) of the pattern portion 120, in the X-axis (FIG. 3), may be formed to decrease along the Z-axis, from the reflective portion 130 toward the substrate 110. Also, as shown in FIG. 3, the pattern portion 120 may include an area, e.g., portion 120be, exposed without being covered by the bank 115. Therefore, the pattern portion 120 may be expressed as terms such as a groove, a slit, a trench, a bank slit and a bank trench. As shown in FIG. 3, the pattern portion 120 may include a bottom surface 120b and an inclined surface 120s. The pattern portion 120 may be disposed to be adjacent to the light extraction portion 140. In some embodiments, the exposed portion 120be is part of the bottom surface 120b.

The reflective portion 130 according to one example may be formed to be concave along a profile of the pattern portion 120 formed to be concave in the non-light emission area NEA, thereby being formed to be concave in the non-light emission area NEA. The reflective portion 130 may be made of a material capable of reflecting light, and may reflect light, which is emitted from the light emission area EA and directed toward the adjacent subpixel SP, toward the light emission area EA of the subpixel SP for emitting light. As shown in FIG. 3, since the reflective portion 130 is disposed to be inclined on the pattern portion 120 while surrounding the light emission area EA, the reflective portion 130 may be expressed as terms such as a side reflective portion or an inclined reflective portion.

Meanwhile, the display apparatus 100 according to one embodiment of the present disclosure may be implemented in a bottom emission type in which light emitted from the light emission area EA is emitted to the lower surface of the substrate 110. Therefore, in the display apparatus 100 according to one embodiment of the present disclosure, the light emitted to the lower surface of the substrate 110 may be the light in which direct light emitted from the light emission area EA and directly emitted to the lower surface of the substrate 110 and reflective light obtained by reflecting the light, which is emitted from the light emission area EA and directed toward the adjacent subpixel SP, by the reflective portion 130 and emitting the light to the lower surface of the substrate 110 are combined with each other. Therefore, the display apparatus 100 according to one embodiment of the present disclosure may more improve light extraction efficiency than the display apparatus in which the reflective portion 130 disposed to be inclined is not provided.

In the display apparatus 100 according to one embodiment of the present disclosure, each of the plurality of subpixels SP may include the light extraction portion 140. The light extraction portion 140 may be formed on the overcoat layer 113 (or the first layer 1131) to overlap the light emission area EA of the subpixel. The light extraction portion 140 may be formed on the overcoat layer 113, e.g., on the first layer 1131 of the overcoat layer 113, of the light emission area EA to have a curved (or uneven) shape, thereby changing a propagation path of light emitted from the light emitting element layer E to increase light extraction efficiency. For example, the light extraction portion 140 may be a non-flat portion, an uneven pattern portion, a micro lens portion, or a light scattering pattern portion.

The light extraction portion 140 may include a plurality of concave portions 141. The plurality of concave portions 141 may be formed to be concave inside the overcoat layer 113. For example, the plurality of concave portions 141 may be formed or configured to be concave from an upper surface 1131a of a first layer 1131 included in the overcoat layer 113. Therefore, the first layer 1131 may include a plurality of concave portions 141. The first layer 1131 may be disposed between the substrate 110 and the light emitting element layer E.

A second layer 1132 of the overcoat layer 113 may be disposed between the first layer 1131 and a light emitting element layer E, e.g., a pixel electrode 114 of the light emitting element layer E shown in FIG. 3. The second layer 1132 according to one example may be formed to be wider than the pixel electrode 114 in a first direction (X-axis direction). Thus, the second layer 1132 may partially overlap the light emissive area EA. The pixel electrode 114 is disposed on the upper surface 1132a of the second layer 1132. In some implementations, the upper surface 1132a of the second layer 1132 may be provided flat.

The pixel electrode 114 is formed on the upper surface 1132a of the second layer 1132 so that the pixel electrode 114 may be provided to be flat, and the light emitting layer 116 and the reflective electrode 117, which are formed on the pixel electrode 114, may be provided to be also flat. In some implementations, the pixel electrode 114, the light emitting layer 116, the reflective electrode 117, that is, the light emitting element layer E is provided to be flat in the light emission area EA, and a thickness of each of the pixel electrode 114, the light emitting layer 116 and the reflective electrode 117 in the light emission area EA may be uniformly formed. Therefore, the light emitting layer 116 may be uniformly emitted without deviation in the light emission area EA.

Also, an upper surface 1132a of the second layer 1132 may be provided to be flat so that the pixel electrode 114 may be provided to be flat, whereby occurrence of a radial rainbow pattern and a radial circular ring pattern due to reflection of external light may be suppressed or minimized as compared with the case that a pixel electrode is formed in a curved shape or an uneven shape.

For example, in case of a display apparatus in which a pixel electrode is provided to be flat, incident external light may be linearly polarized through a polarizing plate and changed to left circularly polarized light while passing through a λ/4 retarder, and the left circularly polarized light may be reflected once on the pixel electrode (or a reflective electrode) and changed to right circularly polarized light by a phase change of 180°. The right circularly polarized light may be linearly polarized to be opposite to the incident light while passing through the λ/4 retarder, and then may become the same as an absorption axis of the polarizing plate and thus may be absorbed into the polarizing plate.

However, in the display apparatus that includes a pixel electrode (or a reflective electrode) formed in a curved shape or an uneven shape, due to curve of the pixel electrode (or the reflective electrode), external light is reflected twice on the pixel electrode (or the reflective electrode) so that a phase is additionally changed as much as 180° as compared with the case that the external light is reflected once, whereby the incident light and the output light have the same phase by passing through the retarder and thus pass through the polarizing plate. Therefore, in the display apparatus that includes a pixel electrode formed in a curved shape or an uneven shape, reflectance of external light may be increased to generate a radial rainbow pattern and a radial circular ring pattern, and black visibility may be deteriorated or black gap may occur.

Therefore, in the display apparatus 100 according to one embodiment of the present disclosure, the upper surface 1132a of the second layer 1132 may be provided to be flat so that the pixel electrode 114 may be provided to be flat, whereby occurrence of a radial rainbow pattern and a radial circular ring pattern due to reflection of external light may be suppressed or minimized as compared with the case that the pixel electrode (or the reflective electrode) is formed in a curved shape or an uneven shape, and real black visibility may be implemented in a non-driving or off state or black gap may be improved.

Meanwhile, in the display apparatus 100 according to one embodiment of the present disclosure, the light extraction portion 140, which includes the plurality of concave portions 141, may be formed to overlap the light emission area EA, instead of the pixel electrode 114 (or the reflective electrode) being provided to be flat, whereby occurrence of the rainbow pattern and the circular ring pattern may be suppressed and light extraction efficiency of the light emitted from the light emission area may be improved.

Referring to FIG. 3, the refractive index of the second layer 1132 included in the overcoat layer 113 may be greater than that of the first layer 1131. As a result, a path of the light emitted from the light emitting layer 116 and directed toward the substrate 110 may be changed toward the light emission area EA (or the reflective portion 130) due to a difference in refractive index between the second layer 1132 and the first layer 1131 of the overcoat layer 113. Therefore, the light that is refracted by the light extraction portion 140 without being reflected by the reflective portion 130 and emitted toward the light emission area EA may be defined as direct light. In addition, since the light having a path formed toward the reflective portion 130 by the light extraction portion 140 may be reflected by the reflective portion 130 and then emitted toward the light emission area EA of the subpixel SP for emitting light, the light may be defined as reflective light.

As shown in FIG. 3, the reflective light may include first reflective light L1 (or WG mode extraction light L1) reflected from the reflective portion 130 and emitted to the substrate 110 after being subjected to optical waveguide through total reflection between the pixel electrode 114 and the reflective electrode 117, second reflective light L2 reflected from the reflective portion 130 and emitted to the substrate 110 after its path is changed by the light extraction portion 140, and third reflective light L3 (or substrate mode extraction light L3) primarily reflected by the reflective portion 130 after being emitted from the light emitting layer 116, secondarily reflected on a boundary surface between a lower surface of the substrate 110 and an air layer and thirdly reflected by the reflective portion 130 and then emitted to the substrate 110. The first reflective light L1, the second reflective light L2 and the third reflective light L3, which are shown in solid lines in FIG. 3, may be the reflective light extracted by being reflected by the reflective portion 130.

As shown in FIG. 3, the first reflective light L1 according to one example may be emitted from the light emission area EA. The second reflective light L2 may be emitted from a position spaced apart from the light emission area EA. That is, the second reflective light L2 may be emitted from the non-light emission area NEA or a peripheral area. Since a pixel driving line for pixel driving, for example, a data line DL is disposed between the first reflective light L1 and the second reflective light L2, a portion of the light reflected from the reflective portion 130 is covered by the data line DL and thus cannot be emitted toward the substrate 110. Therefore, as shown in FIG. 3, the second reflective light L2 may be emitted toward the substrate 110 from the position spaced apart from the light emission area EA, but is not limited thereto. The first reflective light L1 may be emitted toward the substrate 110 from the position spaced apart from the light emission area EA. The third reflective light L3 may be emitted from the light emission area EA or the non-light emission area NEA.

The display apparatus 100 according to one embodiment of the present disclosure may further include light which is emitted to the substrate 110 through the light extraction portion 140 without being reflected by the reflective portion 130. For example, as shown in FIG. 3, the display apparatus 100 may further include first extraction light L4 emitted from the light emitting layer 116, incident on the second layer 1132 and non-reflected on a boundary surface between the first layer 1131 (or the concave portion 141) and the second layer 1132 to pass through the first layer 1131, and second extraction light L5 emitted from the light emitting layer 116, incident on the second layer 1132 and reflected on the boundary surface between the first layer 1131 (or the concave portion 141) and the second layer 1132 at least once to pass through the first layer 1131. The second extraction light L5 is emitted after being reflected on the boundary surface between the first layer 1131 and the second layer 1132, and thus may be expressed as recycle light. Therefore, the display apparatus 100 according to one embodiment of the present disclosure may improve overall light extraction efficiency through the light extraction portion 140 and the reflective portion 130.

The display apparatus 100 according to one embodiment of the present disclosure is provided so that the optimal radius R_{BEST} of the concave portion 141 included in the light extraction portion 140 satisfies an equation such as R_{BEST}=0.15 sin 4π(AR+0.05)+1.5noc+0.5m−0.59, thereby maximizing light extraction efficiency. This will be described later.

In the display apparatus 100 according to one embodiment of the present disclosure, the pattern portion 120 is disposed to surround the light emission area EA, and at least a portion of the reflective portion 130 on the pattern portion 120 may be disposed to surround the light emission area EA. Therefore, the reflective light may be emitted toward the substrate 110 from the position spaced apart from the light emission area EA while surrounding at least a portion of the light emission area EA. Therefore, in the display apparatus 100 according to one embodiment of the present disclosure, since light dissipated by waveguide (or optical waveguide) and/or light dissipated by the interface total reflection may be emitted from the non-light emission area NEA in the form of reflective light through the reflective portion 130 surrounding at least a portion of the light emission area EA, light extraction efficiency may be improved and the overall light emission efficiency may be increased.

Hereinafter, reference to FIGS. 1 to 4B, the display apparatus 100 according to an embodiment of the present specification will be described in more detail.

Referring to FIGS. 1 and 3, the display apparatus 100 according to one embodiment of the present disclosure may include a display panel having a gate driver GD, a light extraction portion 140 overlapping a light emission area EA, a source drive integrated circuit (hereinafter, referred to as “IC”) 150, a flexible film 160, a circuit board 170, and a timing controller 180.

The display panel may include a substrate 110 and an opposite substrate 200 (shown in FIG. 3).

The substrate 110 may include a thin film transistor, and may be a transistor array substrate, a lower substrate, a base substrate, or a first substrate. The substrate 110 may be a transparent glass substrate or a transparent plastic substrate. The substrate 110 may include a display area DA and a non-display area NDA.

The display area DA is an area where an image is displayed, and may be a pixel array area, an active area, a pixel array unit, a display unit, or a screen. For example, the display area DA may be disposed at a central portion of the display panel. The display area DA may include a plurality of pixels P.

The opposite substrate 200 may encapsulate (or seal) the display area DA disposed on the substrate 110. For example, the opposite substrate 200 may be bonded to the substrate 110 via an adhesive member (or clear glue). The opposite substrate 200 may be an upper substrate, a second substrate, or an encapsulation substrate.

The gate driver GD supplies gate signals to the gate lines in accordance with the gate control signal input from the timing controller 180. The gate driver GD may be formed on one side of the display area DA or in the non-display area NDA outside both sides of the display area DA in a gate driver in panel (GIP) method, as shown in FIG. 1.

The non-display area NDA is an area on which an image is not displayed, and may be a peripheral area, a signal supply area, an inactive area or a bezel area. The non-display area NDA may be configured to be in the vicinity of the display area DA. That is, the non-display area NDA may be disposed to surround the display area DA.

A pad area PA may be disposed in the non-display area NDA. The pad area PA may supply a power source and/or a signal for outputting an image to the pixel P provided in the display area DA. Referring to FIG. 1, the pad area PA may be provided above the display area DA.

The source drive IC 150 receives digital video data and a source control signal from the timing controller 180. The source drive IC 150 converts the digital video data into analog data voltages in accordance with the source control signal and supplies the analog data voltages to the data lines. When the source drive IC 150 is manufactured as a driving chip, the source drive IC 150 may be packaged in the flexible film 160 in a chip on film (COF) method or a chip on plastic (COP) method.

Pads, such as data pads, may be formed in the non-display area NDA of the display panel. Lines connecting the pads with the source drive IC 150 and lines connecting the pads with lines of the circuit board 170 may be formed in the flexible film 160. The flexible film 160 may be attached onto the pads by using an anisotropic conducting film, whereby the pads may be connected with the lines of the flexible film 160.

The circuit board 170 may be attached to the flexible films 160. A plurality of circuits implemented as driving chips may be packaged in the circuit board 170. For example, the timing controller 180 may be packaged in the circuit board 170. The circuit board 170 may be a printed circuit board or a flexible printed circuit board.

The timing controller 180 receives the digital video data and a timing signal from an external system board through a cable of the circuit board 170. The timing controller 180 generates a gate control signal for controlling an operation timing of the gate driver GD and a source control signal for controlling the source drive ICs 150 based on the timing signal. The timing controller 180 supplies the gate control signal to the gate driver GD, and supplies the source control signal to the source drive ICs 150.

Referring to FIG. 2, the substrate 110 according to an example may include the light emission area EA and the non-light emission area NEA.

The light emission area EA is an area from which light is emitted, and may mean an area that is not covered by a bank 115. A light emitting element layer E, which includes a pixel electrode 114, a light emitting layer 116 and a reflective electrode 117, may be disposed in the light emission area EA. When an electric field is formed between the pixel electrode 114 and the reflective electrode 117, the light emitting layer 116 in the light emission area EA may emit light.

The light emission area EA according to an example may include gate lines, data lines, pixel driving power lines, and a plurality of pixels P. Each of the plurality of pixels P may include a plurality of subpixels SP that may be defined by the gate lines and the data lines.

Meanwhile, at least four subpixels, which are provided to emit different colors of light and disposed to be adjacent to one another, among the plurality of subpixels SP may constitute one pixel P (or unit pixel). One pixel P may include, but is not limited to, a red subpixel, a green subpixel, a blue subpixel and a white subpixel. One pixel P may include three subpixels SP provided to emit light of different colors of light and disposed to be adjacent to one another. For example, one pixel P may include a red subpixel, a green subpixel and a blue subpixel.

Each of the plurality of subpixels SP includes a thin film transistor and a light emitting element layer E connected to the thin film transistor. Each of the plurality of subpixels may include a light emitting layer (or an organic light emitting layer) interposed between the pixel electrode and the reflective electrode.

The light emitting layer respectively disposed in the plurality of subpixels SP may individually emit light of different colors or emit white light in common. Since the light emitting layer of each of the plurality of subpixels SP commonly emit white light, each of the red subpixel, the green subpixel and the blue subpixel may include a color filter CF (or wavelength conversion member CF) for converting white light into light of its respective different color. In this case, the white subpixel may not include a color filter.

In the display apparatus 100 according to one embodiment of the present disclosure, an area provided with a red color filter may be a red subpixel or a first subpixel, an area provided with a green color filter may be a green subpixel or a second subpixel, an area provided with a blue color filter may be a blue subpixel or a third subpixel, and an area in which the color filter is not provided may be a white subpixel or a fourth subpixel.

Each of the subpixels SP supplies a predetermined current to the organic light emitting element in accordance with a data voltage of the data line when a gate signal is input from the gate line by using the thin film transistor. For this reason, the light emitting layer of each of the subpixels may emit light with a predetermined brightness in accordance with the predetermined current.

The plurality of subpixels SP according to one example may be disposed to be adjacent to each other in a first direction (X-axis direction). The first direction (X-axis direction) may be a horizontal direction based on FIG. 1. The horizontal direction may be a direction in which a gate line is disposed.

A second direction (Y-axis direction) is a direction crossing the first direction (X-axis direction), and may be a vertical direction based on FIG. 1. The vertical direction may be a direction in which a data line is disposed.

A third direction (Z-axis direction) is a direction crossing each of the first direction (X-axis direction) and the second direction (Y-axis direction), and may be a thickness direction of the display apparatus 100.

The plurality of subpixels SP may include a first subpixel SP1, a second subpixel SP2, a third subpixel SP3 and a fourth subpixel SP4 arranged adjacent to each other in the first direction (X-axis direction). For example, the first subpixel SP1 may be a red subpixel, the second subpixel SP2 may be a green subpixel, the third subpixel SP3 may be a blue subpixel and the fourth subpixel SP4 may be a white subpixel, but is not limited thereto. However, the arrangement order of the first subpixel SP1, the second subpixel SP2, the third subpixel SP3 and the fourth subpixel SP4 may be changed.

Each of the first to fourth subpixels SP1 to SP4 may include a light emission area EA and a circuit area. The light emission area EA may be disposed at one side (or an upper side) of a subpixel area, and the circuit area may be disposed at the other side (or a lower side) of the subpixel area. For example, the circuit area may be disposed at the lower side of the light emission area EA based on the second direction Y. The light emission areas EA of the first to fourth subpixels SP1 to SP4 may have same sizes (or areas) as each other, or different sizes (or areas) as each other.

The first to fourth subpixels SP1 to SP4 may be disposed to be adjacent to one another along the first direction (X-axis direction). For example, two data lines extended along the second direction (Y-axis direction) may be disposed in parallel with each other between the first subpixel SP1 and the second subpixel SP2 and between the third subpixel SP3 and the fourth subpixel SP4. A pixel power line extended along the first direction (X-axis direction) may be disposed between the light emission area EA and the circuit area of each of the first to fourth subpixels SP1 to SP4. The gate line and a sensing line may be disposed below the circuit area. The pixel power line EVDD (shown in FIG. 2) extended along the second direction (Y-axis direction) may be disposed at one side of the first subpixel SP1 or the fourth subpixel SP4. A reference line RL extended along the second direction (Y-axis direction) may be disposed between the second subpixel SP2 and the third subpixel SP3. The reference line may be used as a sensing line for sensing a change of characteristics of a driving thin film transistor and/or a change of characteristics of the light emitting element layer, which is disposed in the circuit area, from the outside in a sensing driving mode of the pixel P. The data lines, the pixel power line EVDD and the reference line may be included in the plurality of lines. The data lines may include a first data line DL for driving the first subpixel SP1, a second data line DL for driving the second subpixel SP2, a third data line DL for driving the third subpixel SP3 and a fourth data line DL for driving the fourth subpixel SP4.

A plurality of lines may be provided below the pattern portion 120. Each of the plurality of lines may at least partially overlap the pattern portion 120 below the pattern portion 120. For example, as shown in FIG. 3, the first data line DL may partially overlap the bottom surface 120b of the pattern portion 120 between the first subpixel SP1 and the second subpixel SP2. The second data line DL may partially overlap the inclined surface 120s of the pattern portion 120. The pixel power line or the reference line may partially overlap the bottom surface 120b and the inclined surface 120s of the pattern portion 120.

The bottom surface 120b of the pattern portion 120 according to one embodiment is a surface formed to be closest to the substrate 110, or may be disposed to be closer to the substrate 110 (or the upper surface of the substrate) than the pixel electrode 114 (or the lower surface of the pixel electrode 114) in the light emission area EA. Therefore, as shown in FIG. 3, the bottom surface 120b of the pattern portion 120 may be provided with the same or deeper depth as each of the plurality of concave portions 141, e.g., bottom surface 120b has a same distance as or closer to the substrate layer 110 than the plurality of concave portions 141 in the Z-axis. If the depth of the pattern portion 120 is lower than the depth of the concave portion 141, the area of the inclined reflection portion 130 may be reduced, and thus light extraction efficiency may be reduced. Therefore, in the display apparatus 100 according to one embodiment of the present disclosure, the depth of the pattern portion 120 may be provided to be equal to or deeper than that of the concave portion 141.

The inclined surface 120s of the pattern portion 120 may be disposed between the bottom surface 120b and the light extraction portion 140. Therefore, the inclined surface 120s of the pattern portion 120 may be provided to surround the light emission area EA or the plurality of concave portions 141. As shown in FIG. 3, the inclined surface 120s may be connected to the bottom surface 120b. The inclined surface 120s may form a predetermined angle θ with the bottom surface 120b. For example, the angle θ formed by the inclined surface 120s and the bottom surface 120b may be an obtuse angle. Therefore, a width of the pattern portion 120 may be gradually reduced toward a direction (or the third direction (Z-axis direction)) from the opposing substrate 200 (or the reflective portion 130) toward the substrate 110. As the obtuse angle is formed by the inclined surface 120s and the bottom surface 120b, the bank 115 and the reflective portion 130, which are formed in a subsequent process, may be formed to be concave along the profile of the pattern portion 120. Therefore, the reflective portion 130 may be formed to be concave on the pattern portion 120 formed to be concave in the non-light emission area NEA (or the peripheral area).

As shown in FIG. 3, the pattern portion 120 may be provided to surround the light emission area EA. As the pattern portion 120 is provided to surround the light emission area EA, at least a portion of the reflective portion 130 disposed on the pattern portion 120 may be provided to surround the light emission area EA. Therefore, in the display apparatus 100 according to one embodiment of the present disclosure, since light may be extracted even from the non-light emission area NEA near the light emission area EA, overall light efficiency may be improved. Therefore, the display apparatus 100 according to one embodiment of the present disclosure may have the same light emission efficiency or more improved light emission efficiency even with low power as compared with a general display apparatus having no pattern portion 120 and reflective portion 130, whereby overall power consumption may be reduced.

In addition, the display apparatus 100 according to one embodiment of the present disclosure may allow the light emitting element layer E to emit light even with low power, thereby improving lifespan of the light emitting element layer E.

Referring to FIG. 2, the pattern portion 120 may include a first pattern line 121 disposed in the first direction (X-axis direction) between the circuit area CA and the light emission area EA and a second pattern line 122 disposed in the second direction (Y-axis direction) crossing the first direction (X-axis direction). Referring to FIG. 2, the first pattern line 121 may mean the pattern portion 120 disposed in a horizontal direction, and the second pattern line 122 may mean the pattern portion 120 disposed in a vertical direction.

The first pattern line 121 may include a bottom surface and an inclined surface. The second pattern line 122 may include a bottom surface 122b and an inclined surface 122s. Since each of the bottom surface and the inclined surface of the first pattern line 121 and each of the bottom surface 122b and the inclined surface 122s of the second pattern line 122 are the same as each of the bottom surface 120b and the inclined surface 120s of the pattern portion 120, their description thereof is replaced with the description of the bottom surface 120b and the inclined surface 120s of the pattern portion 120. The first pattern line 121 and the second pattern line 122 may be connected to one in the non-light emission area NEA (or the peripheral area) to surround the light emission area EA.

The second layer 1132 of the overcoat layer 113 may be further extended from the light emission area EA to the non-light emission area NEA to partially cover the inclined surface 120s of the pattern portion 120. Therefore, as shown in FIG. 2, an end 1132c of the second layer 1132 may be in contact with the bottom surface 120b of the pattern portion 120. In this case, the end 1132c of the second layer 1132 may be in contact with only a portion of the bottom surface 120b. When the second layer 1132 entirely covers the bottom surface 120b, the depth of the reflective portion 130 formed on the pattern portion 120 may be relatively lowered, thereby reducing reflective efficiency. Therefore, in the display apparatus 100 according to one embodiment of the present disclosure, the second layer 1132 is provided to be in contact with only a portion of the bottom surface 120b without entirely covering the bottom surface 120b of the pattern portion 120 and thus the reflective portion 130 formed in a subsequent process may be formed to be close to the bottom surface 120b, whereby reflective efficiency may be improved.

The bank 115 may be extended to cover the inclined surface 1132b of the second layer 1132 covering the inclined surface 120s of the pattern portion 120 while covering the edge of the pixel electrode 114. Therefore, the bank 115 may be in contact with a portion of the bottom surface 120b of the pattern portion 120, which is not covered by the second layer 1132. When the bank 115 entirely covers the bottom surface 120b, the depth of the reflective portion 130 formed on the pattern portion 120 is lowered, whereby reflective efficiency may be reduced. Therefore, as shown in FIG. 3, each of the second layer 1132 and the bank 115 on the bottom surface 120b of the pattern portion 120 may be discontinuously provided. That is, each of the second layer 1132 and the bank 115 may be disconnected on the bottom surface 120b of the pattern portion 120. As a result, in the display apparatus 100 according to one embodiment of the present disclosure, the bank 115 is provided to be in contact with only a portion of the bottom surface 120b without entirely covering the bottom surface 120b, so that the reflective portion 130 formed in a subsequent process may be formed to be close to the bottom surface 120b, whereby reflective efficiency may be improved.

In some implementations, the bank 115 is provided to be in contact with only a portion of the bottom surface 120b of the pattern portion 120, as shown in FIG. 3, and the bank 115 may be disconnected from the pattern portion 120. Since FIG. 3 is a cross-section of FIG. 2, a part of the pattern portion 120 in which the bank 115 is disconnected may be a second pattern line 122. Therefore, the bank 115 may be disconnected from the second pattern line 122. As the bank 115 is disconnected from the second pattern line 122, the reflective portion 130 disposed on the second pattern line 122 may be disposed to be close to the bottom surface 122b of the second pattern line. Therefore, since the reflective portion 130 may be formed as deep as possible in the second pattern line 122 as compared with the case that the bank is not disconnected from the second pattern line, reflection efficiency may be improved. Since the second pattern line 122 is disposed between subpixels SP for emitting different colors of light, color mixture or color distortion may be prevented from occurring between the subpixels SP for emitting different colors of light.

Hereinafter, a structure of each of the plurality of subpixels SP will be described in detail.

Referring to FIG. 3, the display apparatus 100 according to one embodiment of the present disclosure may further include a buffer layer BL, a circuit element layer, a thin film transistor (not shown), a pixel electrode 114, a bank 115, a light emitting layer 116, a reflective electrode 117, an encapsulation layer 118 and a color filter CF.

In more detail, each of the subpixels SP according to one embodiment may include a circuit element layer provided on an upper surface of a buffer layer BL, including a gate insulating layer (not shown), an interlayer insulating layer 111 and a passivation layer 112, an overcoat layer 113 provided on the circuit element layer, a pixel electrode 114 provided on the overcoat layer 113, a bank 115 covering an edge of the pixel electrode 114, a light emitting layer 116 on the pixel electrode 114 and the bank 115 (or on the pixel electrode 114 and in the non-light emission area NEA), a reflective electrode 117 on the light emitting layer 116, and an encapsulation layer 118 on the reflective electrode 117.

The thin film transistor for driving the subpixel SP may be disposed on the circuit element layer. The circuit element layer may be expressed in terms of an inorganic film layer. The pixel electrode 114, the light emitting layer 116 and the reflective electrode 117 may be included in the light emitting element layer E.

The buffer layer BL may be formed between the substrate 110 and the gate insulating layer to protect the thin film transistor. The buffer layer BL may be disposed on the entire surface (or front surface) of the substrate 110. The reference line RL for pixel driving may be disposed between the buffer layer BL and the passivation layer 112. The buffer layer BL may serve to block diffusion of a material contained in the substrate 110 into a transistor layer during a high temperature process of a manufacturing process of the thin film transistor. Optionally, the buffer layer BL may be omitted in some cases.

The thin film transistor (or a drive transistor) according to an example may include an active layer, a gate electrode, a source electrode, and a drain electrode. The active layer may include a channel area, a drain area and a source area, which are formed in a thin film transistor area of a circuit area of the subpixel SP. The drain area and the source area may be spaced parallel to each other with the channel area interposed therebetween.

The active layer may be formed of a semiconductor material based on any one of amorphous silicon, polycrystalline silicon, oxide and organic material.

The gate insulating layer may be formed on the channel area of the active layer. As an example, the gate insulating layer may be formed in an island shape only on the channel area of the active layer, or may be formed on an entire front surface of the substrate 110 or the buffer layer BL, which includes the active layer.

The gate electrode may be formed on the gate insulating layer to overlap the channel area of the active layer.

The interlayer insulating layer 111 may be formed to partially overlap the gate electrode and the drain area and source area of the active layer. The interlayer insulating layer 111 may be formed over the entire light emission area where light is emitted in the circuit area and the subpixel SP.

The source electrode may be electrically connected to the source area of the active layer through a source contact hole provided in the interlayer insulating layer 111 overlapped with the source area of the active layer. The drain electrode may be electrically connected to the drain area of the active layer through a drain contact hole provided in the interlayer insulating layer 111 overlapped with the drain area of the active layer.

The drain electrode and the source electrode may be made of the same metal material. For example, each of the drain electrode and the source electrode may be made of a single metal layer, a single layer of an alloy or a multi-layer of two or more layers, which is the same as or different from that of the gate electrode.

In addition, the circuit area may further include first and second switching thin film transistors disposed together with the thin film transistor, and a capacitor. Since each of the first and second switching thin film transistors is provided on the circuit area of the subpixel SP to have the same structure as that of the thin film transistor, its description will be omitted. The capacitor (not shown) may be provided in an overlap area between the gate electrode and the source electrode of the thin film transistor, which overlap each other with the interlayer insulating layer 111 interposed therebetween.

Additionally, in order to prevent a threshold voltage of the thin film transistor provided in a pixel area from being shifted by light, the display panel or the substrate 110 may further include a light shielding layer (not shown) provided below the active layer of at least one of the thin film transistor, the first switching thin film transistor or the second switching thin film transistor. The light shielding layer may be disposed between the substrate 110 and the active layer to shield light incident on the active layer through the substrate 110, thereby minimizing a change in the threshold voltage of the transistor due to external light. Also, since the light shielding layer is provided between the substrate 110 and the active layer, the thin film transistor may be prevented from being seen by a user.

The passivation layer 112 may be provided on the substrate 110 to cover the pixel area. The passivation layer 112 covers a drain electrode, a source electrode and a gate electrode of the thin film transistor, and the buffer layer. The reference line may be disposed between the passivation layer 112 and the interlayer insulating layer 111. The reference line may be disposed at a position symmetrical to the pixel power line based on the light emission area EA or a similar position symmetrical to the pixel power line. Therefore, the reference line and the pixel power line may be disposed below the bank 115 without covering the light emitting area EA. The passivation layer 112 may be formed over the circuit area and the light emission area. The passivation layer 112 may be omitted. The color filter CF may be disposed on the passivation layer 112.

The overcoat layer 113 may be provided on the substrate 110 to cover the passivation layer 112 and the color filter CF. When the passivation layer 112 is omitted, the overcoat layer 113 may be provided on the substrate 110 to cover the circuit area. The overcoat layer 113 may be formed in the circuit area in which the thin film transistor is disposed and the light emission area EA. In addition, the overcoat layer 113 may be formed in the other non-display area NDA except a pad area PA of the non-display area NDA and the entire display area DA. For example, the overcoat layer 113 may include an extension portion (or an enlarged portion) extended or enlarged from the display area DA to the other non-display area NDA except the pad area PA. Therefore, the overcoat layer 113 may have a size relatively wider than that of the display area DA.

The overcoat layer 113 according to one example may be formed to have a relatively thick thickness, thereby providing a flat surface on the display area DA and the non-display area NDA. For example, the overcoat layer 113 may be made of an organic material such as photo acryl, benzocyclobutene, polyimide and fluorine resin.

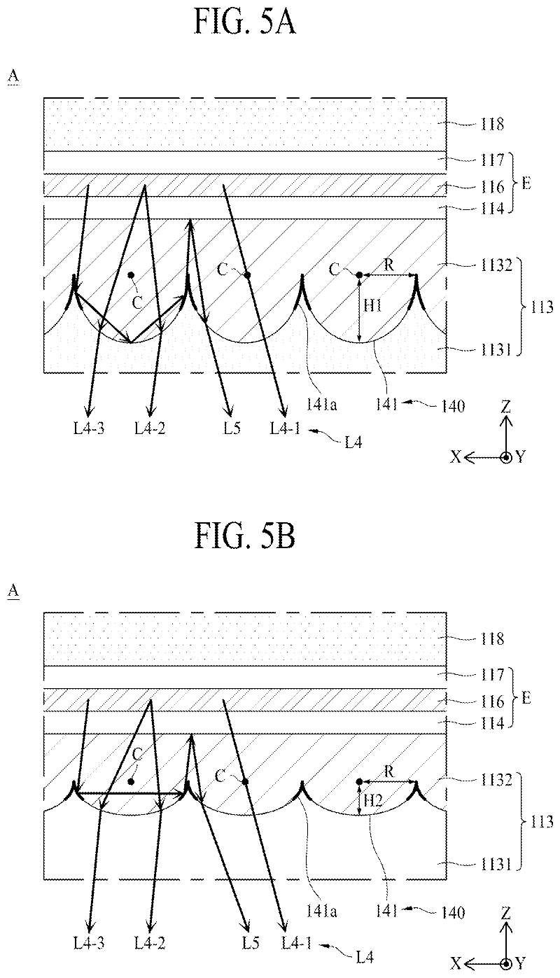

The overcoat layer 113 formed in the display area DA (or the light emission area EA) may include a plurality of concave portions 141. The plurality of concave portions 141 are the elements of the light extraction portion 140 for increasing light efficiency of the light emission area EA, and may be formed inside the overcoat layer 113. In detail, as shown in FIG. 5, the plurality of concave portions 141 may be formed in a concave shape on the first layer 1131 of the overcoat layer 113. The plurality of concave portions 141 are provided to be connected to each other so that an embossed shape (or in the form of a plurality of consecutive lenses) may be formed in the first layer 1131.

The second layer 1132 having a refractive index higher than that of the first layer 1131 may be formed on the first layer 1131. A path of the light, which is directed toward the adjacent subpixel SP, among the light emitted from the light emitting element layer E may be changed toward the reflective portion 130 (or toward the light emission area (EA)) in accordance with a difference in the refractive index between the second layer 1132 and the first layer 1131. The second layer 1132 may be provided to cover the embossed shape (or in the form of a plurality of consecutive lenses) of the first layer 1131 and thus the upper surface 1132a may be provided to be flat.

The pixel electrode 114 is formed on the upper surface 1132a of the second layer 1132 so that the pixel electrode 114 may be provided to be flat, and the light emitting layer 116 and the reflective electrode 117, which are formed on the pixel electrode 114, may be provided to be also flat. Since the pixel electrode 114, the light emitting layer 116, the reflective electrode 117, that is, the light emitting element layer E is provided to be flat in the light emission area EA, a thickness of each of the pixel electrode 114, the light emitting layer 116 and the reflective electrode 117 in the light emission area EA may be uniformly formed. Therefore, the light emitting layer 116 may be uniformly emitted without deviation in the light emission area EA.

The plurality of concave portions 141 may be formed on the first layer 1131 through a photo process using a mask having an opening portion and then a patterning (or etching) or ashing process after the first layer 1131 is coated to cover the passivation layer 112 and the color filter CF.

The plurality of concave portions 141 may be formed in an area overlapped with the color filter CF and/or an area that is not overlapped with the bank 115 of the non-light emission area NEA, but are not limited thereto. A portion of the plurality of concave portions 141 may be formed to overlap the bank 115.

Referring back to FIG. 3, the color filter CF disposed in the light emission area EA may be provided between the substrate 110 and the overcoat layer 113. Therefore, the color filter CF may be disposed between the pixel power line, for example, the data line DL and the reflective portion 130 or between the reference line RL and the pattern portion 120. The color filter CF may include a red color filter (or a first color filter) CF1 for converting white light emitted from the light emitting layer 116 into red light, a green color filter (or a second color filter) CF2 for converting white light into green light, and a blue color filter (or a third color filter) CF3 for converting white light into blue light. The fourth subpixel, which is a white subpixel, may not include a color filter since the light emitting layer 116 emits white light.

As shown in FIG. 3, the display apparatus 100 according to one embodiment of the present disclosure may be provided such that color filters having different colors partially overlap each other at a boundary portion of the plurality of subpixels SP. In this case, the display apparatus 100 according to one embodiment of the present disclosure may prevent the light emitted from each subpixel SP from being emitted to the adjacent subpixel SP due to the color filters overlapped with each other at the boundary portion of the subpixels SP, thereby preventing color mixture between the subpixels SP from occurring.

The pixel electrode 114 of the subpixel SP may be formed on the overcoat layer 113. The pixel electrode 114 may be connected to a drain electrode or a source electrode of the thin film transistor through a contact hole passing through the overcoat layer 113 and the passivation layer 112. The edge portion of the pixel electrode 114 may be covered by the bank 115.

Because the display apparatus 100 according to an embodiment of the present disclosure is configured as the bottom emission type, the pixel electrode 114 may be formed of a transparent conductive material (or TCO), such as indium tin oxide (ITO) or indium zinc oxide (IZO) capable of transmitting light, or a semi-transmissive conductive material such as magnesium (Mg), silver (Ag), or an alloy of Mg and Ag.

Meanwhile, the material constituting the pixel electrode 114 may include MoTi. The pixel electrode 114 may be a first electrode or an anode electrode.

The bank 115 is an area from which light is not emitted, and may be provided to surround each of the light emitting portions (or the concave portions 141) of each of the plurality of subpixels SP. That is, the bank 115 may partition (or define) the concave portions 141 of each of the light emitting portion or the subpixels SP. The light emitting portion may mean a portion where the pixel electrode 114 and the reflective electrode 117 are in contact with each of the upper surface and the lower surface of the light emitting layer 116 with the light emitting layer 116 interposed therebetween.

The bank 115 may be formed to cover the edge of each pixel electrode 114 of each of the subpixels SP and expose a portion of each of the pixel electrodes 114. That is, the bank 115 may partially cover the pixel electrode 114. Therefore, the bank 115 may prevent the pixel electrode 114 and the reflective electrode 117 from being in contact with each other at the end of each pixel electrode 114. The exposed portion of the pixel electrode 114, which is not covered by the bank 115, may be included in the light emitting portion (or the light emission area EA). As shown in FIG. 3, the light emitting portion may be formed on the plurality of concave portions 141, and thus the light emitting portion (or the light emission area EA) may overlap the concave portions 141 in a thickness direction (or the third direction (Z-axis direction)) of the substrate 110.

After the bank 115 is formed, the light emitting layer 116 may be formed to cover the pixel electrode 114 and the bank 115. Therefore, a portion of the bank 115 may be provided between the pixel electrode 114 and the light emitting layer 116 in the non-light emission area NEA. The bank 115 may be expressed as the term of a pixel defining layer. The bank 115 according to one example may include an organic material and/or an inorganic material. As shown in FIG. 3, the bank 115 may be formed to be concave or inclined along the profile of the pattern portion 120 (or the second layer 1132).

Referring again to FIG. 3, the light emitting layer 116 may be formed on the pixel electrode 114 and the bank 115. The light emitting layer 116 may be provided between the pixel electrode 114 and the reflective electrode 117. Thus, when a voltage is applied to each of the pixel electrode 114 and the reflective electrode 117, an electric field is formed between the pixel electrode 114 and the reflective electrode 117. Therefore, the light emitting layer 116 may emit light. The light emitting layer 116 may be formed of a plurality of subpixels SP and a common layer provided on the bank 115.

The light emitting layer 116 according to an embodiment may be provided to emit white light. The light emitting layer 116 may include a plurality of stacks which emit lights of different colors. For example, the light emitting layer 116 may include a first stack, a second stack, and a charge generating layer (CGL) provided between the first stack and the second stack. The light emitting layer may be provided to emit the white light, and thus, each of the plurality of subpixels SP may include a color filter CF suitable for a corresponding color.

The first stack may be provided on the pixel electrode 114 and may be implemented in a structure where a hole injection layer (HIL), a hole transport layer (HTL), a blue emission layer (EML(B)), and an electron transport layer (ETL) are sequentially stacked.

The charge generating layer may supply an electric charge to the first stack and the second stack. The charge generating layer may include an N-type charge generating layer for supplying an electron to the first stack and a P-type charge generating layer for supplying a hole to the second stack. The N-type charge generating layer may include a metal material as a dopant.

The second stack may be provided on the first stack and may be implemented in a structure where a hole transport layer (HTL), a yellow-green (YG) emission layer (EML(YG)), and an electron injection layer (EIL) are sequentially stacked.

In the display apparatus 100 according to an embodiment of the present disclosure, because the light emitting layer 116 is provided as a common layer, the first stack, the charge generating layer, and the second stack may be arranged all over the plurality of subpixels SP.

The reflective electrode 117 may be formed on the light emitting layer 116. The reflective electrode 117 may be disposed in the light emission area EA and the non-light emission area NEA. The reflective electrode 117 according to one example may include a metal material. The reflective electrode 117 may reflect the light emitted from the light emitting layer 116 in the plurality of subpixels SP toward the lower surface of the substrate 110. Therefore, the display apparatus 100 according to one embodiment of the present disclosure may be implemented as a bottom emission type display apparatus.

The display apparatus 100 according to one embodiment of the present disclosure is a bottom emission type and has to reflect light emitted from the light emitting layer 116 toward the substrate 110, and thus the reflective electrode 117 may be made of a metal material having high reflectance. The reflective electrode 117 according to one example may be formed of a metal material having high reflectance such as a stacked structure (Ti/Al/Ti) of aluminum and titanium, a stacked structure (ITO/Al/ITO) of aluminum and ITO, an Ag alloy and a stacked structure (ITO/Ag alloy/ITO) of Ag alloy and ITO. The Ag alloy may be an alloy such as silver (Ag), palladium (Pd) and copper (Cu). The reflective electrode 117 may be expressed as terms such as a second electrode, a cathode electrode and a counter electrode.

Meanwhile, in the display apparatus 100 according to one embodiment of the present disclosure, the reflective portion 130 may be a portion of the reflective electrode 117. Therefore, the reflective portion 130 may reflect light, which is directed toward the adjacent subpixel SP, toward the light emission area EA of the subpixel SP for emitting light. Since the reflective portion 130 is a portion of the reflective electrode 117, as shown in FIG. 3, the reflective portion 130 may be denoted by a reference numeral 117a. In the present disclosure, the reflective portion 130 may mean the reflective electrode 117 that overlaps the pattern portion 120. In particular, the reflective portion 130 may mean the reflective electrode 117 that is inclined while being overlapped with the pattern portion 120. Therefore, as shown in FIG. 3, the reflective portion 130 may reflect light that is directed toward the adjacent subpixel SP, or light that is dissipated through total reflection between interfaces, toward the light emission area EA (or the non-light emission area NEA) of the subpixel SP for emitting light.

The encapsulation layer 118 is formed on the reflective electrode 117. The encapsulation layer 118 serves to prevent oxygen or moisture from being permeated into the light emitting layer 116 and the reflective electrode 117. To this end, the encapsulation layer 118 may include at least one inorganic film and at least one organic film.

Meanwhile, as shown in FIG. 2, the encapsulation layer 118 may be disposed not only in the light emission area EA but also in the non-light emission area NEA. The encapsulation layer 118 may be disposed between the reflective electrode 117 and an opposing substrate 200.

In the display apparatus 100 according to one embodiment of the present disclosure, the pattern portion 120 may be provided near the light emission area EA (or the non-light emission area NEA) and the reflective portion 130 may be provided on the pattern portion 120 in order to prevent light extraction efficiency from being reduced as some of the light emitted from the light emitting element layer is not discharged to the outside due to total reflection on an interface between the light emitting element layer and the electrode and/or an interface between the substrate and the air layer. The reflective portion 130 may be disposed to be inclined along the profile of the pattern portion 120.

Also, the display apparatus 100 according to one embodiment of the present disclosure may be provided with the light extraction portion 140 that includes a plurality of concave portions 141 below the pixel electrode 114 to overlap the light emission area EA in order to improve light extraction efficiency.

In case of a general organic light emitting (OLED) display apparatus, it is necessary to design a thickness of an element capable of minimizing surface plasmons, a waveguide mode and a substrate mode and having the greatest light extraction efficiency. However, since the waveguide mode and the surface plasmons have a trade-off relation in which surface plasmons is enhanced when the waveguide mode is low, it is important to increase light extraction efficiency of recycle light in the substrate mode. That is, when light extraction efficiency by the waveguide mode is increased, light loss due to the surface plasmons is increased, and when light extraction efficiency by the surface plasmons is increased, light loss due to the waveguide mode is increased, whereby light extraction efficiency may be improved in the substrate mode. Therefore, in the display apparatus 100 according to one embodiment of the present disclosure, the light extraction portion 140 having a plurality of concave portions 141 may be formed below the light emitting element layer E (or the pixel electrode), whereby light extraction efficiency may be improved the substrate mode.

The surface plasmons means a phenomenon in which a waveguide mode of a magnetic field component of an electromagnetic wave reacts with a free electron in a metal to move along a boundary surface of the metal, for example, a cathode electrode (or pixel electrode). The waveguide mode means a phenomenon in which reflection and re-reflection of light are repeated along a length direction of the pixel electrode (or the cathode electrode) when a thickness between the metal and the metal, for example, between the pixel electrode and the cathode electrode is similar to a size of a wavelength of light that is emitted, whereby reinforcement occurs and the light moves by the reinforcement. The substrate mode may mean that light, which excludes light lost by the waveguide mode and/or the surface plasmons from the light emitted from the light emitting layer, is emitted to the air layer Air (or the outside) by passing through the layers existing between the pixel electrode and the substrate 110. Therefore, the substrate mode may be expressed as an air mode.

Meanwhile, the display apparatus 100 according to one embodiment of the present disclosure is provided so that the optimal radius R of the concave portion 141 satisfies R_{BEST}=0.15 sin 4π(AR+0.05)+1.5n_{oc}+0.5m−0.59, whereby light extraction efficiency in the substrate mode may be maximized, and thus overall light efficiency may be improved. In this case, π is a circumferential rate (or ‘π’ is the ratio of a circle's circumference to its diameter (i.e., π=3.14159 . . . )), AR is an aspect ratio (or a horizontal and vertical ratio) of each of the plurality of concave portions, ‘n_{oc}’ is a refractive index of the first layer 1131, and ‘m’ is a variable value according to a process of forming the plurality of concave portions 141.

FIG. 4A is a schematic view illustrating a light path of a display apparatus having a light extraction portion according to a comparative example, and FIG. 4B is a schematic view illustrating a light path of a display apparatus according to one embodiment of the present disclosure.

Referring to FIG. 4A, in case of the display apparatus having no light extraction portion (or concave portion), light extraction efficiency may be reduced as some of the light emitted from a light emitting layer EL is not emitted to the outside due to total reflection on the interface between an electrode E1 and a substrate G and/or between the substrate G and the air layer Air.

In detail, as shown in FIG. 4A, the display apparatus having no light extraction portion may have a structure in which a substrate G, a first electrode E1, a light emitting layer EL and a second electrode E2 are stacked. In this case, the first electrode E1, the light emitting layer EL and the second electrode E2 may correspond to the pixel electrode 114, the light emitting layer 116 and the reflective electrode 117 of the display apparatus according to the present disclosure. The substrate G includes layers below the first electrode E1, and may include, for example, at least one of the overcoat layer 113, the passivation layer 112, the interlayer insulating layer 111 or the substrate 110 of the display apparatus according to the present disclosure. As shown in the comparative example of FIG. 4A, light emitted from the light emitting layer EL includes first total reflection light CL1 which is totally reflected on the boundary surface between the first electrode E1 and the substrate G and wave-guided, and second total reflection light CL2 which is totally reflected on the interface between the substrate G and the air layer Air and trapped inside the substrate G. The light may be partially emitted to the outside of the substrate G.

For example, light, which is incident toward the substrate G at a first incident angle θ1, among the light emitted from the light emitting layer EL may be totally reflected at a first emission angle θ1′ opposite to the incident angle on the boundary surface between the substrate G and the air layer Air. The second total reflective light CL2 totally reflected as above may be trapped inside the substrate G and then dissipated. Therefore, as shown in FIG. 4A, the display apparatus having no light extraction portion may deteriorate light efficiency due to the waveguide and the light trapped inside the substrate.

On the other hand, as shown in FIG. 4B, a display apparatus 100 according to one embodiment of the present disclosure may be provided with a light extraction portion 140 including a plurality of concave portions 141 on the lower surface of a second layer 1132. Therefore, the display apparatus 100 of the present disclosure of FIG. 4B may have a structure in which the second layer 1132, the pixel electrode 114, the light emitting layer 116 and the reflective electrode 117 are stacked on the light extraction portion 140. As shown in FIG. 4B, light emitted from the light emitting layer EL may include light that is wave-guided by being totally reflected on the boundary surface between the pixel electrode 114 and the second layer 1132. However, in the display apparatus 100 according to one embodiment of the present disclosure, the plurality of concave portions 141 having a curved shape (or a lens shape) are provided on the lower surface of the second layer 1132, so that the lower surface of the second layer 1132 (or the upper surface of the first layer 1131) may be provided in a curved shape (or a lens shape) instead of a flat shape. Therefore, in the display apparatus 100 according to one embodiment of the present disclosure, since there is no change in a refractive index from the upper surface of the second layer 1132 to the lower surface of the second layer 1132 (or the upper surface of the first layer 1131) having a curved shape, the light directed toward the plurality of concave portions 141 may be emitted without refraction (or without change of the light path). As shown in FIG. 4B, light, which is emitted in a direction perpendicular to a normal line of the concave portion 141, among the light emitted through the concave portion 141 may be emitted in a straight line shape. The light emitted through the concave portion 141 may be included in the first extraction light L4, or may include first sub-extraction light L4-1 and second sub-extraction light L4-2 as shown in FIG. 4A.

For example, the light L4-1, which is incident toward the concave portion 141 at the first incident angle θ1, among the light emitted from the light emitting layer EL may not be reflected on the boundary surface (or the concave portion 141) between the lower surface of the second layer 1132 having the curved shape (or lens shape) and the air layer Air, and may be emitted to the air layer Air without being refracted in a direction perpendicular to the normal line of the boundary surface. In this case, the first incident angle θ1 may refer to an angle at which light is incident on a vertical virtual line passing through the center of the concave portion 141.

Therefore, as shown in FIG. 4B, the display apparatus 100 according to one embodiment of the present disclosure may further improve light extraction efficiency by minimizing or reducing the light trapped inside the substrate as compared with the display apparatus of the comparative example, which has no light extraction portion.

Hereinafter, the light extraction portion 140 will be described in detail with reference to FIGS. 5A and 5B.

FIG. 5A is a cross-sectional view illustrating an example of a portion A of FIG. 3, and FIG. 5B is a cross-sectional view illustrating another example of a portion A of FIG. 3.

Referring to FIGS. 5A and 5B, in the display apparatus 100 according to one embodiment of the present disclosure, the optimal radius R_{BEST} of the concave portion 141 may be provided to satisfy R_{BEST}=0.15 sin 4π(AR+0.05)+1.5n_{oc}+0.5m−0.59. ‘π’ is a circumferential rate, AR is an aspect ratio (or a horizontal and vertical ratio) of each of the plurality of concave portions, ‘n_{oc}’ is a refractive index of the first layer 1131, and ‘m’ is a variable value according to a process of forming the plurality of concave portions 141.

The aspect ratio AR of the concave portion 141 may be a ratio of a vertical distance from the center C of the concave portion 141 in the second layer 1132 to the first layer 1131 with respect to a radius R of the concave portion 141. The vertical distance may be the distance in a direction parallel with a third direction (Z-axis direction).

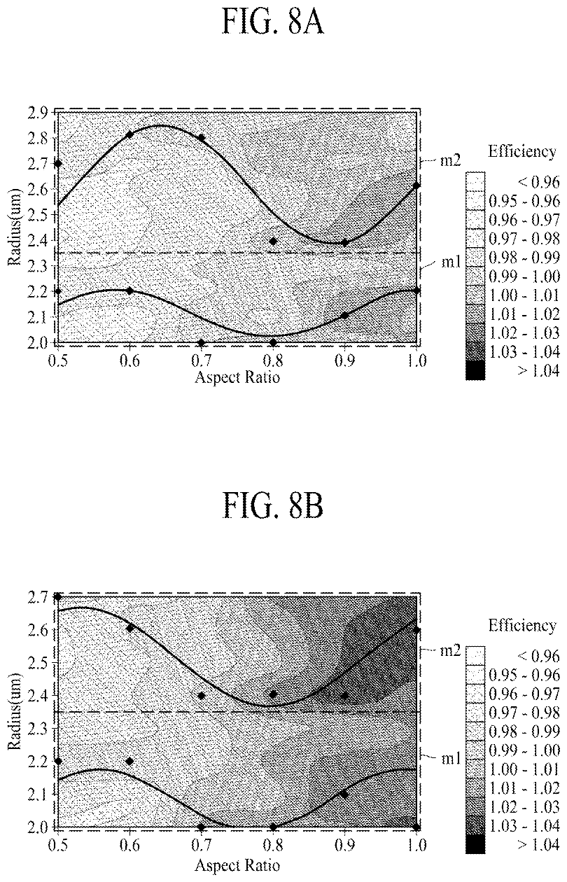

The variable value ‘m’ according to the process of forming the concave portion 141 may be 1 when the radius R of the concave portion 141 is 2 um to 2.35 um, and may be 2 when the radius R of the concave portion 141 exceeds 2.35 um and is 2.9 um or less. That is, since the case that the variable value ‘m’ according to the process of forming the concave portion 141 is 1 corresponds to the case that the concave portion 141 is formed to be small, a fine process may be performed. In contrast, since the case that the variable value ‘m’ according to the process of forming the concave portion 141 is 2 corresponds to the case that the concave portion 141 is formed to be great, a normal process may be performed. Therefore, the variable value ‘m’ according to the process of forming the concave portion 141 may be a value derived (or set) in accordance with the process of forming the concave portion 141. This will be described in detail with reference to FIGS. 8A and 8B.

As shown in FIG. 5A, the concave portion 141 according to one example may be formed in a shape having a radius R and a first vertical distance H1. In this case, the first vertical distance H1 may be greater than the radius R. Therefore, in the display apparatus 100 according to FIG. 5A, the concave portion 141 may have an aspect ratio AR greater than 1, and thus may be provided in the form of an inverted bell.

The display apparatus 100 according to FIG. 5A is provided in the form of a bell in which the aspect ratio AR of the concave portion 141 is greater than 1, so that the first extraction light L4 and/or the second extraction light L5 may be refracted to be small on the boundary surface between the first layer 1131 and the second layer 1132. For example, the first extraction light L4 may include first sub-extraction light L4-1 passing through the center C of the concave portion 141, second sub-extraction light L4-2 passing through a right side of the center C of the concave portion 141 based on FIG. 5A, and third sub-extraction light L4-3 passing through a left side of the center C of the concave portion 141 based on FIG. 5A. Since the first sub-extraction light L4-1 is emitted in a direction perpendicular to the normal line of the concave portion 141 by passing through the center C of the concave portion 141, the first sub-extraction light L4-1 may be emitted in a straight line without refraction. Since the second sub-extraction light L4-2 passes through the right side of the center C of the concave portion 141, the second sub-extraction light L4-2 may be output by being refracted toward the left side on the boundary surface. Since the third sub-extraction light L4-3 passes through the left of the center C of the concave portion 141, the third sub-extraction light L4-3 may be emitted by being refracted toward the right side on the boundary surface.

In the display apparatus 100 according to FIG. 5A, the second extraction light L5 is primarily reflected on a side 141a at a left side of the curved surface of the concave portion 141, secondarily reflected on a middle surface between the sides of the concave portion 141 and then thirdly reflected on the side 141a at a right side of the curved surface of the concave portion 141. The light thirdly reflected on the side 141a at the right side of the curved surface of the concave portion 141 may be output by being refracted on the boundary surface between the first layer 1131 and the second layer 1132 after being reflected on the lower surface of the pixel electrode 114 (or the lower surface of the reflective electrode 117). In this case, in the display apparatus 100 according to FIG. 5A, since the aspect ratio of the concave portion 141 is greater than 1, the second extraction light L5 may be refracted to be small on the boundary surface between the first layer 1131 and the second layer 1132. Therefore, since the display apparatus 100 according to FIG. 5A has a small refraction angle bent toward the left or right side on the boundary surface, front light extraction efficiency may be improved. The side 141a at the left or right side of the concave portion 141 may mean a predetermined area of a curved surface in a direction from a start portion of the curved surface toward a depth of the concave portion 141.

Also, in the display apparatus 100 according to FIG. 5A, since the aspect ratio of the concave portion 141 is greater than 1, an area of the side 141a of the curved surface of the concave portion 141 may be greater than the case that the aspect ratio of the concave portion 141 is 1 or less.

Therefore, in the display apparatus 100 according to FIG. 5A, since the amount of light reflected by the side 141a of the curved surface of the concave portion 141 may be increased, light extraction efficiency of the second extraction light L5 may be more increased than the case that the aspect ratio of the concave portion 141 is 1 or less.

Meanwhile, as shown in FIG. 5B, the concave portion 141 according to another example may be formed in a shape having a radius R and a second vertical distance H2. In this case, the second vertical distance H2 may be smaller than the radius R. Therefore, in the display apparatus 100 according to FIG. 5B, the concave portion 141 may be provided in the form of a wide lens or bowl because the aspect ratio AR may be smaller than 1.

The display apparatus 100 according to FIG. 5B is provided in a bowl shape in which the aspect ratio AR of the concave portion 141 is less than 1, so that the first extraction light L4 and/or the second extraction light L5 may be significantly refracted on the boundary surface between the first layer 1131 and the second layer 1132. For example, the first extraction light L4 may include first sub-extraction light L4-1 passing through the center C of the concave portion 141, second sub-extraction light L4-2 passing through the right side of the center C of the concave portion 141 based on FIG. 5B, and third sub-extraction light L4-3 passing through the left side of the center C of the concave portion 141 based on FIG. 5B. Since the first sub-extraction light L4-1 is emitted in a direction perpendicular to the normal line of the concave portion 141 by passing through the center C of the concave portion 141, the first sub-extraction light L4-1 may be emitted in a straight line without refraction. Since the second sub-extraction light L4-2 passes through the right side of the center C of the concave portion 141, the second sub-extraction light L4-2 may be emitted by being refracted toward the left side on the boundary surface. Since the third sub-extraction light L4-3 passes through the left side of the center C of the concave portion 141, the third sub-extraction light L4-3 may be emitted by being refracted toward the right side on the boundary surface.

Meanwhile, in the display apparatus 100 according to FIG. 5B, the second extraction light L5 may be primarily reflected on the side 141a at the left side of the curved surface of the concave portion 141 and may be secondarily reflected on the side 141a at the right side of the curved surface of the concave portion 141. The light secondarily reflected on the side 141a at the right side of the curved surface of the concave portion 141 may be emitted by being refracted on the boundary surface between the first layer 1131 and the second layer 1132 after being reflected on the lower surface of the pixel electrode 114 (or the lower surface of the reflective electrode 117). In this case, in the display apparatus 100 according to FIG. 5B, since the aspect ratio of the concave portion 141 is smaller than 1, the second extraction light L5 may be greatly refracted on the boundary surface between the first layer 1131 and the second layer 1132. Therefore, since the display apparatus 100 according to FIG. 5B has a great refraction angle bent toward the left or right side on the boundary surface, the luminance viewing angle may be improved.

Also, in the display apparatus 100 according to FIG. 5B, since the aspect ratio of the concave portion 141 is smaller than 1, an area of the side 141a of the curved surface of the concave portion 141 may be smaller than the case that the aspect ratio of the concave portion 141 is greater than 1. Therefore, in the display apparatus 100 according to FIG. 5B, since the amount of light passing through the middle surface between the sides of the curved surface of the concave portion 141 may be more increased than the amount of light reflected by the side 141a of the curved surface of the concave portion 141, light extraction efficiency of the first extraction light L4 may be more increased than the case that the aspect ratio of the concave portion 141 is greater than 1.

Hereinafter, the first extraction light L4 and the second extraction light L5 of the display apparatus 100 according to one embodiment of the present disclosure will be described in view of the efficiency increasing rate according to the luminance viewing angle.

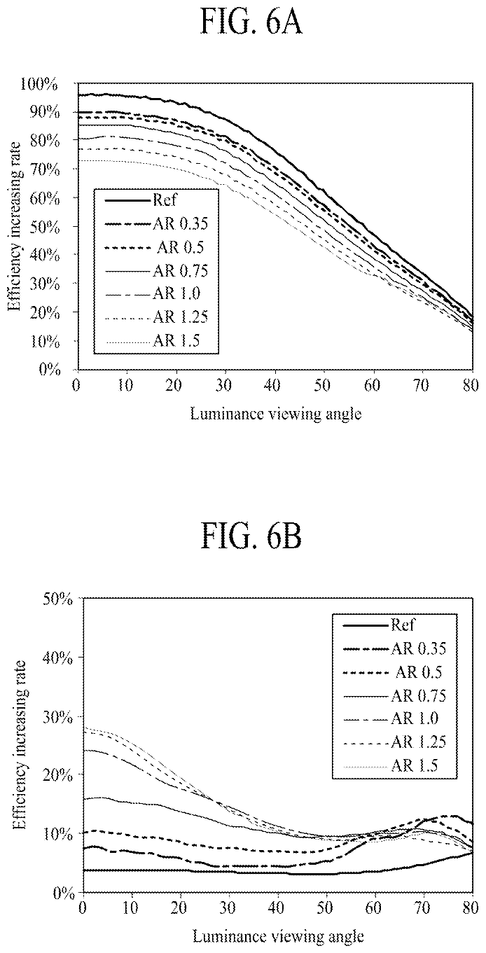

FIG. 6A is a graph illustrating an efficiency increasing rate based on a luminance viewing angle of first extraction light of a display apparatus according to one embodiment of the present disclosure, and FIG. 6B is a graph illustrating an efficiency increasing rate based on a luminance viewing angle of second extraction light of a display apparatus according to one embodiment of the present disclosure.

Referring to FIG. 6A, a horizontal axis is a luminance viewing angle, and a vertical axis is an efficiency increasing rate. In this case, the efficiency increasing rate may mean a light efficiency increasing rate. A thick solid line Ref is a graph of an efficiency increasing rate based on a luminance viewing angle of first extraction light in the display apparatus (or the display apparatus of the comparative example) having no plurality of concave portions 141, a thick alternate long and short dash line is a graph of an efficiency increasing rate based on the luminance viewing angle of the first extraction light when the aspect ratio of the concave portion 141 is 0.35, and a thick dotted line is a graph of an efficiency increasing rate based on the luminance viewing angle of the first extraction light when the aspect ratio of the concave portion 141 is 0.5. A middle sold line thinner than the thick solid line is a graph of an efficiency increasing rate based on the luminance viewing angle of the first extraction light when the aspect ratio of the concave portion 141 is 0.75, a middle alternate long and short dash line thinner than the thick alternate long and short dash line is a graph of an efficiency increasing rate based on the luminance viewing angle of the first extraction light when the aspect ratio of the concave portion 141 is 1, a middle dotted line thinner than the thick dotted line is a graph of an efficiency increasing rate based on the luminance viewing angle of the first extraction light when the aspect ratio of the concave portion 141 is 1.25, and a thin solid line thinner than the middle solid line is a graph of an efficiency increasing rate based on the luminance viewing angle of the first extraction light when the aspect ratio of the concave portion 141 is 1.5.

As shown in FIG. 6A, the light efficiency increasing rate of the first extraction light L4 may be greater as the aspect ratio AR of the concave portion 141 becomes smaller. For example, in the case that the luminance viewing angle is 10, the light efficiency increasing rate of the first extraction light of the display apparatus of the comparative example may be 95%, when the aspect ratio of the concave portion 141 is 0.35, the light efficiency increasing rate of the first extraction light is may be 90%, when the aspect ratio of the concave portion 141 is 0.5, the light efficiency increasing rate of the first extraction light may be 88%, when the aspect ratio of the concave portion 141 is 0.75, the light efficiency increasing rate of the first extraction light may be 85%, when the aspect ratio of the concave portion 141 is 1, the light efficiency increasing rate of the first extraction light may be 80%, when the aspect ratio of the concave portion 141 is 1.25, the light efficiency increasing rate of the first extraction light may be 78%, and when the aspect ratio of the concave portion 141 is 1.5, the light efficiency increasing rate of the first extraction light may be 72%.

Therefore, it can be seen that the light efficiency increasing rate of the first extraction light L4 is the highest in the display apparatus according to the comparative example, which has no plurality of concave portions 141 (or light extraction portion). However, as shown in FIG. 6B, the display apparatus according to the comparative example, which has no plurality of concave portions 141 (or light extraction portion), has the lowest light efficiency increasing rate of the second extraction light L5. Therefore, the display apparatus according to the comparative example, which has no plurality of concave portions 141 (or light extraction portion), has a problem in that overall light efficiency of the extraction light obtained by summing the light efficiency increasing rates of the first extraction light L4 and the second extraction light L5 is low.

On the contrary, since the display apparatus 100 according to one embodiment of the present disclosure includes the plurality of concave portions 141, the light efficiency increasing rate of the first extraction light L4 is slightly smaller than that of the display apparatus according to the comparative example, but the light efficiency increasing rate of the second extraction light L5 is significantly greater than that of the display apparatus according to the comparative example, whereby overall light efficiency may be higher than that of the display apparatus according to the comparative example. In addition, the display apparatus 100 according to one embodiment of the present disclosure may maximize overall light efficiency because the reflective lights L1, L2 and L3 emitted by being reflected by the reflective portion 130 are added.

Meanwhile, as shown in FIG. 6A, the light efficiency increasing rate of the first extraction light L4 may be greater as the luminance viewing angle becomes smaller. For example, in the case that the aspect ratio of the concave portion 141 is 0.35, it can be seen that the light efficiency increasing rate is 90% when the luminance viewing angle is 10, whereas the light efficiency increasing rate is significantly reduced to 20% when the luminance viewing angle is 80. In the case that the aspect ratio of the concave portion 141 is 0.75, the light efficiency increasing rate is 85% when the luminance viewing angle is 10, whereas the light efficiency increasing rate is significantly reduced to 17% when the luminance viewing angle is 80. The fact that the luminance viewing angle is small may mean that front light extraction efficiency is high. Therefore, the display apparatus 100 according to one embodiment of the present disclosure has a small aspect ratio of the concave portion 141, so that the luminance viewing angle of the first extraction light L4 may be reduced, and front light extraction efficiency may be enhanced. In this case, the display apparatus 100 according to one embodiment of the present disclosure may be applied to a display apparatus requiring privacy and a personal mobile display apparatus.

Referring to FIG. 6B, a horizontal axis is a luminance viewing angle, and a vertical axis is an efficiency increasing rate. A thick solid line is a graph of an efficiency increasing rate based on a luminance viewing angle of second extraction light in the display apparatus (or the display apparatus of the comparative example) having no plurality of concave portions 141, a thick alternate long and short dash line is a graph of an efficiency increasing rate based on the luminance viewing angle of the second extraction light when the aspect ratio of the concave portion 141 is 0.35, and a thick dotted line is a graph of an efficiency increasing rate based on the luminance viewing angle of the second extraction light when the aspect ratio of the concave portion 141 is 0.5. A middle sold line thinner than the thick solid line is a graph of an efficiency increasing rate based on the luminance viewing angle of the second extraction light when the aspect ratio of the concave portion 141 is 0.75, a middle alternate long and short dash line thinner than the thick alternate long and short dash line is a graph of an efficiency increasing rate based on the luminance viewing angle of the second extraction light when the aspect ratio of the concave portion 141 is 1, a middle dotted line thinner than the thick dotted line is a graph of an efficiency increasing rate based on the luminance viewing angle of the second extraction light when the aspect ratio of the concave portion 141 is 1.25, and a thin solid line thinner than the middle solid line is a graph of an efficiency increasing rate based on the luminance viewing angle of the second extraction light when the aspect ratio of the concave portion 141 is 1.5.

As shown in FIG. 6B, the light efficiency increasing rate of the second extraction light L5 may be greater as the aspect ratio AR of the concave portion 141 is increased when the luminance viewing angle is 25 or less. For example, in the case that the luminance viewing angle is 10, when the aspect ratio of the concave portion 141 is 1.5, the light efficiency increasing rate of the second extraction light may be 27%, when the aspect ratio of the concave portion 141 is 1.25, the light efficiency increasing rate of the second extraction light is may be 26%, when the aspect ratio of the concave portion 141 is 1, the light efficiency increasing rate of the second extraction light may be 22%, when the aspect ratio of the concave portion 141 is 0.75, the light efficiency increasing rate of the second extraction light may be 16%, when the aspect ratio of the concave portion 141 is 0.5, the light efficiency increasing rate of the second extraction light may be 10%, when the aspect ratio of the concave portion 141 is 0.35, the light efficiency increasing rate of the second extraction light may be 7%, and the light efficiency increasing rate of the second extraction light of the display apparatus of the comparative example, which has no concave portion 141 may be 4%.

Therefore, it can be seen that the light efficiency increasing rate of the second extraction light L5 becomes greater as the aspect ratio AR of the concave portion 141 is increased when the luminance viewing angle is 25 or less. This is because that the area of the side 141a of the curved surface of the concave portion 141 is increased as the aspect ratio AR of the concave portion 141 is increased.

Referring back to FIG. 6B, the light efficiency increasing rate of the second extraction light L5 may be greater as the aspect ratio AR of the concave portion 141 becomes smaller when the luminance viewing angle is 70 or more. For example, in the case that the luminance viewing angle is 75, when the aspect ratio of the concave portion 141 is 0.35, the light efficiency increasing rate of the second extraction light may be 14%, when the aspect ratio of the concave portion 141 is 0.5, the light efficiency increasing rate of the second extraction light may be 12%, when the aspect ratio of the concave portion 141 is 0.75, the light efficiency increasing rate of the second extraction light may be 10%.

Therefore, it can be seen that the light efficiency increasing rate of the second extraction light L5 is greater as the aspect ratio AR of the concave portion 141 is smaller when the luminance viewing angle is 70 or more. This is because that the area of the side 141a of the curved surface of the concave portion 141 is reduced as the aspect ratio AR of the concave portion 141 is reduced.

As a result, the display apparatus 100 according to one embodiment of the present disclosure may adjust the light efficiency increasing rate based on the luminance viewing angle of the first extraction light L4 and the second extraction light L5 by adjusting the aspect ratio AR of the concave portion 141, thereby maximizing light extraction efficiency in accordance with the purpose of use. As described above, since the optimal radius R_{BEST} of the concave portion satisfies R_{BEST}=0.15 sin 4π(AR+0.05)+1.5n_{oc}+0.5m−0.59, the optimal radius R of the concave portion may be proportional to the aspect ratio AR of the concave portion 141. For example, when the aspect ratio AR of the concave portion is increased, the optimal radius R_{BEST} of the concave portion may be also increased, and when the aspect ratio AR of the concave portion is reduced, the optimal radius R_{BEST} of the concave portion may be also reduced. In the display apparatus 100 according to one embodiment of the present disclosure, the shape of the concave portion 141 (or the shape of the light extraction portion 140) may be optimized to correspond to the above equation, whereby light extraction efficiency of the light emitted from the light emitting element layer E may be maximized.

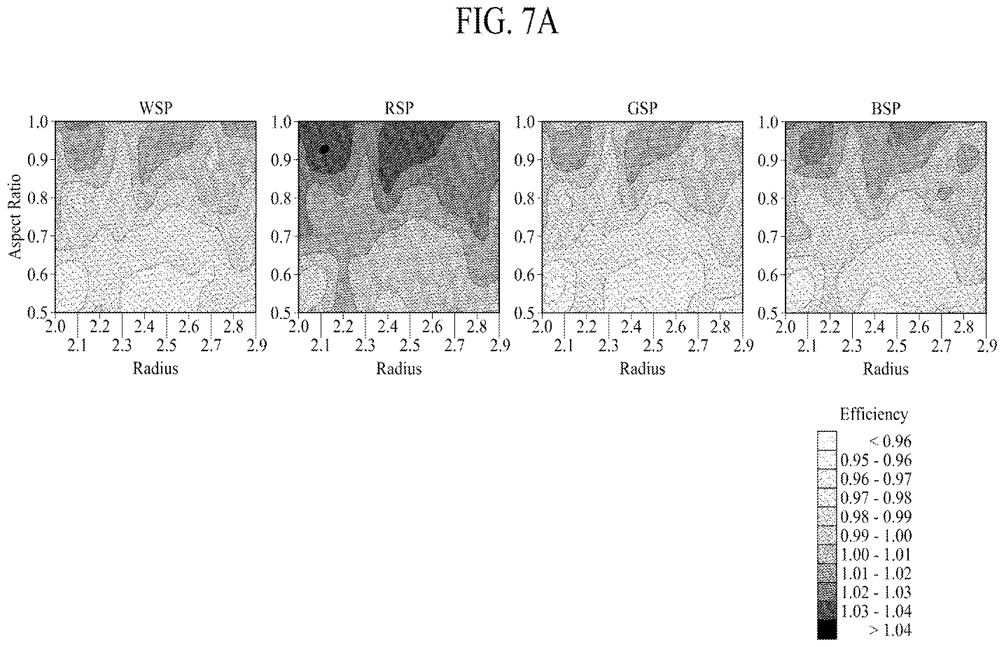

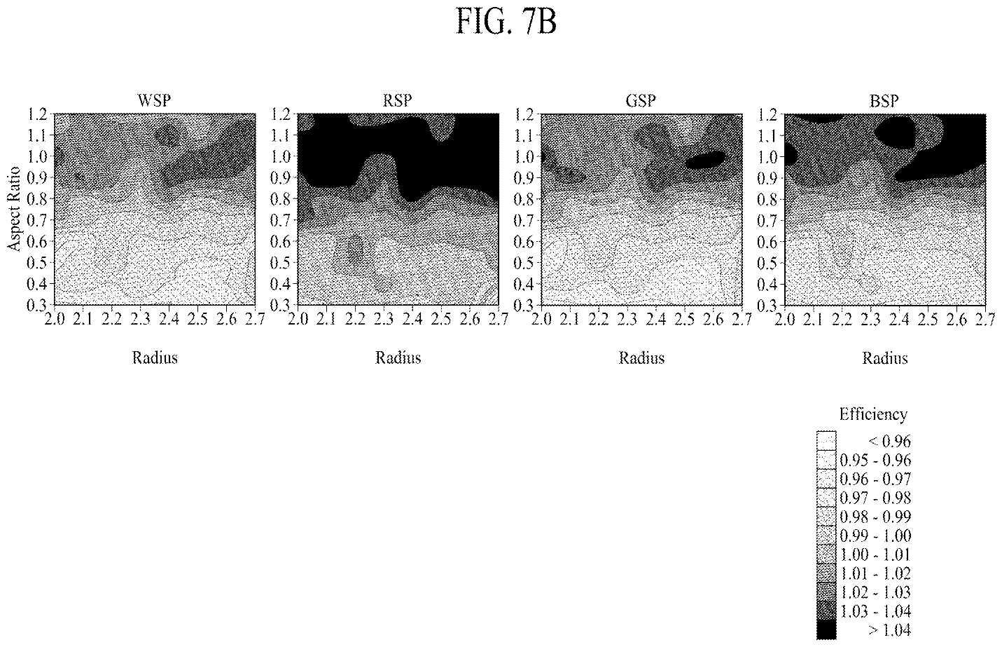

FIG. 7A is a light efficiency map illustrating light efficiency based on a radius of a concave portion and an aspect ratio of the concave portion in each of subpixels when a difference in refractive index between a first layer and a second layer of a display apparatus according to one embodiment of the present disclosure is 0.16, and FIG. 7B is a light efficiency map illustrating light efficiency based on a radius of a concave portion and an aspect ratio of the concave portion in each of subpixels when a difference in refractive index between a first layer and a second layer of a display apparatus according to one embodiment of the present disclosure is 0.2.

The inventor of the display apparatus 100 according to one embodiment of the present disclosure simulated a light efficiency map by adjusting the difference in refractive index between the first layer 1131 and the second layer 1132, and FIGS. 7A and 7B illustrate the light efficiency map based on the simulation. For example, the inventor of the display apparatus 100 according to one embodiment of the present disclosure calculated light efficiency by adjusting the refractive index of the first layer 1131 to 1.47 and 1.43, respectively, after fixing the refractive index of the second layer 1132 to 1.63.

The light efficiency map according to FIG. 7A is the light efficiency map according to the radius R of the concave portion and the aspect ratio AR of the concave portion when the refractive index of the second layer 1132 is 1.63 and the refractive index of the first layer 1131 is 1.47. That is, FIG. 7A is the light efficiency map when the difference in refractive index between the first layer 1131 and the second layer 1132 is 0.16. The light efficiency map according to FIG. 7B is the light efficiency map according to the radius R of the concave portion and the aspect ratio

AR of the concave portion when the refractive index of the second layer 1132 is 1.63 and the refractive index of the first layer 1131 is 1.43. That is, FIG. 7B is the light efficiency map when the difference in refractive index between the first layer 1131 and the second layer 1132 is 0.2.

In detail, FIGS. 7A and 7B illustrate the light efficiency map of each of the plurality of subpixels included in one pixel of the display apparatus 100 according to one embodiment of the present disclosure. For example, the plurality of subpixels may include a white subpixel WSP, a red subpixel RSP, a green subpixel GSP and a blue subpixel BSP. In each of FIGS. 7A and 7B, a horizontal axis is the radius R of the concave portion 141, a vertical axis is the aspect ratio AR of the concave portion 141, and shades represent efficiency (or light efficiency). In this case, it is noted that light efficiency is improved as intensity of shades becomes stronger (or darker). For example, it is noted that, when light efficiency has a value of 1 or more, light efficiency is more improved than the display apparatus having no concave portion.

First, referring to FIG. 7A, it can be seen that each of a white subpixel WSP, a red subpixel RSP, a green subpixel GSP and a blue subpixel BSP has highest light efficiency at each of 2.1 um and 2.5 um of the radius R of the concave portion 141 when the difference in refractive index between the first layer 1131 and the second layer 1132 is 0.16 and the aspect ratio AR of the concave portion 141 is 0.9 or more and 1 or less. For example, it can be seen that the white subpixel WSP has highest light efficiency of 1.01 or more and less than 1.02 when the radius R of the concave portion 141 is 2.1 um and the aspect ratio of the concave portion 141 is 0.9, and has a highest light efficiency of 1.01 or more and less than 1.02 when the radius R of the concave portion 141 is 2.5 um and the aspect ratio of the concave portion 141 is 0.9. For example, it can be seen that the red subpixel RSP has highest light efficiency of 1.03 or more and less than 1.04 when the radius R of the concave portion 141 is 2.1 um and the aspect ratio of the concave portion 141 is 0.9, and has highest light efficiency of 1.03 or more and less than 1.04 when the radius R of the concave portion 141 is 2.5 um and the aspect ratio of the concave portion 141 is 0.9. For example, it can be seen that the green subpixel GSP has highest light efficiency of 1.00 or more and less than 1.01 when the radius R of the concave portion 141 is 2.1 um and the aspect ratio of the concave portion 141 is 0.9, and has highest light efficiency of 1.00 or more and less than 1.01 when the radius R of the concave portion 141 is 2.5 um and the aspect ratio of the concave portion 141 is 0.9. For example, it can be seen that the blue subpixel BSP has highest light efficiency of 1.02 or more and less than 1.03 when the radius R of the concave portion 141 is 2.1 um and the aspect ratio of the concave portion 141 is 0.9, and has highest light efficiency of 1.00 or more and less than 1.01 when the radius R of the concave portion 141 is 2.5 um and the aspect ratio of the concave portion 141 is 0.95. Therefore, in the display apparatus 100 according to one embodiment of the present disclosure, it can be seen that highest light efficiency of 1.00 or more is obtained in each of 2.1 um and 2.5 um of the radius R of the concave portion 141 when the difference in refractive index between the first layer 1131 and the second layer 1132 is 0.16 and the aspect ratio AR of the concave portion 141 is 0.9 or more and 1 or less. As a result, the display apparatus 100 according to one embodiment of the present disclosure may more improve light efficiency than the display apparatus having no concave portion, and may maximize light efficiency of the recycle light by adjusting the difference in refractive index between the first layer 1131 and the second layer 1132 and the radius R and the aspect ratio AR of the concave portion 141.

Then, referring to FIG. 7B, in the case that the difference in refractive index between the first layer 1131 and the second layer 1132 is 0.2, it can be seen that the white subpixel WSP has highest light efficiency when the aspect ratio AR of the concave portion 141 is 0.95 or more and 1.05 or less and the radius R of the concave portion 141 is 2 um and 2.5 um. For example, it can be seen that the white subpixel WSP has highest light efficiency of 1.03 or more and less than 1.04 when the radius R of the concave portion 141 is 2 um and the aspect ratio AR of the concave portion 141 is 0.95 or more and 1.05 or less, and has highest light efficiency of 1.03 or more and less than 1.04 when the radius R of the concave portion 141 is 2.5 um and the aspect ratio AR of the concave portion 141 is 0.95 or more and 1.05 or less.

In the case that the difference in refractive index between the first layer 1131 and the second layer 1132 is 0.2, it can be seen that the red subpixel RSP has highest light efficiency when the aspect ratio AR of the concave portion 141 is 1 or more and 1.05 or less and the radius R of the concave portion 141 is 2 um or more and 2.7 um or less. For example, it can be seen that the red subpixel RSP has highest light efficiency of 1.04 or more when the radius R of the concave portion 141 is 2 um or more and 2.7 um or less and the aspect ratio AR of the concave portion 141 is 1 or more and 1.05 or less.

In the case that the difference in refractive index between the first layer 1131 and the second layer 1132 is 0.2, it can be seen that the green subpixel GSP has highest light efficiency when the aspect ratio AR of the concave portion 141 is 0.96 or more and 1.03 or less and the radius R of the concave portion 141 is 2 um and 2.55 um. For example, it can be seen that the green subpixel

GSP has highest light efficiency of 1.04 or more when the radius R of the concave portion 141 is 2 um and the aspect ratio AR of the concave portion 141 is 0.96 or more and 1.02 or less, and has highest light efficiency of 1.04 or more when the radius R of the concave portion 141 is 2.55 um and the aspect ratio AR of the concave portion 141 is 0.96 or more and 1.02 or less.

In the case that the difference in refractive index between the first layer 1131 and the second layer 1132 is 0.2, it can be seen that the blue subpixel BSP has highest light efficiency when the aspect ratio AR of the concave portion 141 is 0.95 or more and 1.05 or less and the radius R of the concave portion 141 is 2 um and 2.5 um. For example, it can be seen that the blue subpixel BSP has highest light efficiency of 1.04 or more when the radius R of the concave portion 141 is 2 um and the aspect ratio AR of the concave portion 141 is 0.95 or more and 1.05 or less, and has highest light efficiency of 1.04 or more when the radius R of the concave portion 141 is 2.5 um and the aspect ratio AR of the concave portion 141 is 0.95 or more and 1.05 or less.

Therefore, in the display apparatus 100 according to one embodiment of the present disclosure, when the difference in refractive index between the first layer 1131 and the second layer 1132 is 0.2, the aspect ratio AR and the radius R of the concave portion 141 are provided to correspond to each of the subpixels WSP, RSP, GSP and BSP, whereby light efficiency in each of the subpixels may be maximized as compared with the display apparatus having no concave portion.

Consequently, in the display apparatus 100 according to one embodiment of the present disclosure, the difference in refractive index between the first layer 1131 and the second layer 1132 is provided to be 0.16 or more, and the aspect ratio AR and the radius R of the concave portion 141 are provided as the optimal condition as described above, whereby light efficiency may be further improved in each of the subpixels WSP, RSP, GSP and BSP as compared with the display apparatus having no concave portion. That is, in the display apparatus 100 according to one embodiment of the present disclosure, the light extraction efficiency increasing rate of the first extraction light L4 and the second extraction light L5 by the concave portion 141 may be higher as the refractive index of the first layer 1131 (or the low refractive layer) is lower than the second layer 1132 (or the high refractive layer), and the improvement tendency of the light extraction efficiency may be varied depending on the radius R and the aspect ratio AR of the concave portion 141.

Meanwhile, as shown in FIGS. 7A and 7B, it can be seen that light efficiency and a highest light efficiency area in each of the subpixels WSP, RSP, GSP and BSP are higher and wider in the case of FIG. 7B in which the difference in refractive index between the first layer 1131 and the second layer 1132 is 0.2 than the case of FIG. 7A in which the difference in refractive index between the first layer 1131 and the second layer 1132 is 0.16. Therefore, in the display apparatus 100 according to one embodiment of the present disclosure, the difference in refractive index between the first layer 1131 and the second layer 1132 is provided to be 0.2 or more, whereby light efficiency of the recycle light in each of the subpixels WSP, RSP, GSP and BSP may be maximized.

In the display apparatus 100 according to one embodiment of the present disclosure, the difference in refractive index between the first layer 1131 and the second layer 1132 and the aspect ratio AR and the radius R of the concave portion 141 may be provided as an optimal condition through a light efficiency simulation, and the equation related to the aspect ratio AR of the concave portion 141, the radius R of the concave portion 141, the refractive index of the first layer 1131 (or the low refractive layer) and a variable value according to the process of forming the concave portion 141 may be derived based on the optimal condition. As a result, in the display apparatus 100 according to one embodiment of the present disclosure, the optimal radius R_{BEST} of the concave portion 141 may satisfy R_{BEST}=0.15 sin 4π(AR+0.05)+1.5n_{oc}+0.5m−0.59.

Hereinafter, light efficiency based on the variable value, that is, a value of ‘m’ according to the process of forming the concave portion 141 will be described with reference to FIGS. 8A and 8B.

FIG. 8A is a light efficiency map illustrating light efficiency based on a process of forming a concave portion of a white subpixel when a difference in refractive index between a first layer and a second layer of a display apparatus according to one embodiment of the present disclosure is 0.16, and FIG. 8B is a light efficiency map illustrating light efficiency based on a process of forming a concave portion of a white subpixel when a difference in refractive index between a first layer and a second layer of a display apparatus according to one embodiment of the present disclosure is 0.2.

The inventor of the display apparatus 100 according to one embodiment of the present disclosure simulated the light efficiency map by adjusting the difference in refractive index between the first layer 1131 and the second layer 1132 and the radius R and the aspect ratio AR of the concave portion 141, and FIGS. 8A and 8B illustrate the light efficiency map based on the simulation. Referring to FIGS. 8A and 8B, in the display apparatus 100 according to one embodiment of the present disclosure, a maximum light extraction area according to a refractive index, that is, a maximum recycle efficiency area may be classified into two areas depending on the variable value ‘m’ according to the process of forming the concave portion 141. ‘m1’ represents an area of a fine process, in which the radius R of the concave portion 141 is 2 um or more and 2.35 um or less, and ‘m2’ represents an area of a normal process, in which the radius R of the concave portion 141 exceeds 2.35 um and is 2.9 um or less.

Meanwhile, in case of the radius of the concave portion 141, which is less than 2 um, it is difficult to form the concave portion 141 due to the limitation on the process, and in case of the radius of the concave portion 141, which exceeds 2.9 um, a problem occurs in that light lost while passing through the concave portion 141 is increased due to an increase in thickness, which is caused by an increase in the radius. Therefore, in the display apparatus 100 according to one embodiment of the present disclosure, the radius R of the concave portion 141 is provided to be 2 um or more and 2.9 um or less, so that the concave portion 141 may be easily formed while minimizing loss of the light.

FIG. 8A illustrates a light efficiency map of a white subpixel W according to a value of ‘m’ when a refractive index of the first layer 1131 (or low refractive index layer) is 1.47 and the difference in refractive index between the first layer 1131 and the second layer 1132 (or the high refractive index layer) is 0.16. In FIG. 8A, a graph at an upper side is based on a normal process, and a graph at a lower side is based on a fine process. FIG. 8B illustrates a light efficiency map of a white subpixel W according to a value of ‘m’ when a refractive index of the first layer 1131 (or low refractive index layer) is 1.43 and the difference in refractive index between the first layer 1131 and the second layer 1132 (or the high refractive index layer) is 0.2. In FIG. 8B, a graph at an upper side is based on a normal process, and a graph at a lower side is based on a fine process. Referring to FIGS. 8A and 8B, a horizontal axis is the aspect ratio AR of the concave portion 141, and a vertical axis is the radius R of the concave portion 141.

First, referring to FIG. 8A, when dots having highest light efficiency are connected in accordance with the aspect ratio AR of the concave portion 141 in each of m1 and m2, a graph having a shape of a sinewave in each of m1 and m2 may be derived. As shown in FIG. 8A, it can be seen that the sinewaves in m1 and m2 are different from each other only in amplification and their wave shapes are similarly implemented. For example, referring to FIG. 8A, when the aspect ratio AR of the concave portion 141 is 0.6, the radius of the concave portion 141 is 2.2 um and 2.8 um at highest light efficiency of 0.98 or more and less than 0.99, and when the aspect ratio AR of the concave portion 141 is 0.8, the radius of the concave portion 141 is 2 um and 2.5 um at highest light efficiency of 0.99 or more and less than 1, and when the aspect ratio AR of the concave portion 141 is 1.0, the radius of the concave portion 141 is 2.2 um and 2.6 um at highest light efficiency of 1.01 or more and less than 1.02. That is, since the size of the concave portion 141 is small in the fine process m1, a radius difference of the concave portion 141 according to the change in the aspect ratio AR of the concave portion 141 is small to reach about 0.2, and since the size of the concave portion 141 is great in the normal process m2, the radius difference of the concave portion 141 according to the change in the aspect ratio AR of the concave portion 141 is great to reach about 0.3.

Referring to FIG. 8B, when dots having highest light efficiency are connected in accordance with the aspect ratio AR of the concave portion 141 in each of m1 and m2, a graph having a shape of a sinewave in each of m1 and m2 may be derived. As shown in FIG. 8B, it can be seen that the sinewaves in m1 and m2 are different from each other only in amplification and their wave shapes are similarly implemented. For example, referring to FIG. 8B, when the aspect ratio AR of the concave portion 141 is 0.6, the radius of the concave portion 141 is 2.16 um and 2.62 um at highest light efficiency of 0.99 or more and less than 1, and when the aspect ratio AR of the concave portion 141 is 0.8, the radius of the concave portion 141 is 2 um and 2.37 um at highest light efficiency of 1.01 or more and less than 1.02, and when the aspect ratio AR of the concave portion 141 is 0.9, the radius of the concave portion 141 is 2.1 um and 2.47 um at highest light efficiency of 1.03 or more and less than 1.04. That is, since the size of the concave portion 141 is small in the fine process m1, a radius difference of the concave portion 141 according to the change in the aspect ratio AR of the concave portion 141 is small to reach about 0.16, and since the size of the concave portion 141 is great in the normal process m2, the radius difference of the concave portion 141 according to the change in the aspect ratio AR of the concave portion 141 is great to reach about 0.25.

Therefore, the inventor of the display apparatus 100 according to one embodiment of the present disclosure defined the value of ‘m’ as 1 in the fine process m1, in which the size of the concave portion 141 is small, and defined the value of ‘m’ as 2 in the normal process m2, in which the size of the concave portion 141 is great, based on the above simulation result, thereby deriving an equation for the optimal radius R_{BEST} of the concave portion 141 as follows. Therefore, in the display apparatus 100 according to one embodiment of the present disclosure, the optimal radius R_{BEST} of the concave portion 141 may satisfy R_{BEST}=0.15 sin 4π(AR+0.05)+1.5n_{oc}+0.5m−0.59.

Referring to FIGS. 8A and 8B, it can be seen that the radius R of the concave portion 141 is increased as the refractive index of the first layer 1131 (or the low refractive layer) is increased. That is, it can be seen that the radius R of the concave portion 141 is increased as the difference in refractive index between the first layer 1131 and the second layer 1132 (or the high refractive layer) is reduced. As described above with reference to FIGS. 7A and 7B, when the difference in refractive index between the first layer 1131 and the second layer 1132 is small, light extraction efficiency of the recycle light is relatively smaller than the case that the difference in refractive index between the first layer 1131 and the second layer 1132 is great. Therefore, in the display apparatus 100 according to one embodiment of the present disclosure, as the difference in refractive index between the first layer 1131 and the second layer 1132 is provided to be 0.16 or more, light extraction efficiency of the recycle light (or the first extraction light L4 and the second extraction light L5) may be more improved than the case that the difference in refractive index between the first layer 1131 and the second layer 1132 is small. Alternatively, in the display apparatus 100 according to one embodiment of the present disclosure, as the radius R of the concave portion 141 is provided to be small, light extraction efficiency of the recycle light (or the first extraction light L4 and the second extraction light L5) may be more improved than the case that the radius R of the concave portion 141 is great.

Consequently, in the display apparatus 100 according to one embodiment of the present disclosure, the optimal radius R_{BEST} of the concave portion 141 is provided to satisfy R_{BEST}=0.15 sin 4π(AR+0.05)+1.5n_{oc}+0.5m−0.59, so that light extraction efficiency of the recycle light (or the first extraction light L4 and the second extraction light L5) may be maximized, whereby overall light efficiency may be improved.

Also, in the display apparatus 100 according to one embodiment of the present disclosure, the reflective portion 130 is provided on the pattern portion 120 in the periphery of the non-light emission area NEA between the plurality of subpixels, so that light extraction may be performed even in the non-light emission area, whereby overall light efficiency may be improved.

Also, in the display apparatus 100 according to the present disclosure, since light extraction may be performed even in the non-light emission area NEA, the display apparatus 100 according to one embodiment of the present disclosure may have the same light emission efficiency or more improved light emission efficiency even with low power as compared with the display apparatus having no reflective portion, whereby overall power consumption may be reduced.

According to the present disclosure, the following advantageous effects may be obtained.

In the display apparatus according to the present disclosure, each of the plurality of subpixels includes the light extraction portion that includes the plurality of concave portions, so that light extraction efficiency of the light emitted from the light emitting element layer may be improved.

The display apparatus according to the present disclosure may maximize light extraction efficiency of the light emitted from the light emitting element layer by adjusting or controlling the radius of the light extraction portion (or the concave portion).

In the display apparatus according to the present disclosure, the reflective portion is provided on the pattern portion that is in the periphery of the non-light emission area between the plurality of subpixels, so that the light may be extracted even from the non-light emission area, whereby overall light efficiency may be improved.

In the display apparatus according to the present disclosure, since the light may be extracted even from the non-light emission area, the display apparatus according to the present disclosure may have the same light emission efficiency or more improved light emission efficiency even with low power, whereby overall power consumption may be reduced.

It will be apparent to those skilled in the art that the present disclosure described above is not limited by the above-described embodiments and the accompanying drawings and that various substitutions, modifications and variations can be made in the present disclosure without departing from the spirit or scope of the disclosures. Consequently, it is intended that all variations or modifications derived from the meaning, scope and equivalent concept of the claims fall within the scope of the present disclosure.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

What is claimed is:

1. A display apparatus comprising:
a substrate having a plurality of pixels having a plurality of subpixels;
a pattern portion disposed on the substrate and having a first concave portion between subpixels of the plurality of subpixels; and
a reflective portion on the pattern portion,
wherein the plurality of subpixels include an overcoat layer having a first layer on the substrate and a light extraction portion adjacent to the reflective portion, the first layer having a plurality of second concave portions,
a radius R_{BEST} of a second concave portion satisfies R_{BEST}=0.15 sin 4π(AR+0.05)+1.5n_{oc}+0.5m−0.59,
wherein ‘π’ is a circumferential rate, AR is an aspect ratio of the second concave portion, ‘n_{oc}’ is a refractive index of the first layer, and ‘m’ is a variable value.

2. The display apparatus of claim 1, wherein the overcoat layer includes a second layer on the first layer, and
an aspect ratio of the second concave portion is a ratio of a vertical distance from a center of the second concave portion in the second layer to the first layer with respect to a radius of the second concave portion.

3. The display apparatus of claim 1, wherein the variable value is 1 and a radius of the second concave portion is in a range from 2 um to 2.35 um, inclusive, or the variable value is 2 and the radius of the second concave portion exceeds 2.35 um and is 2.9 um or less.

4. The display apparatus of claim 2, wherein the refractive index of the first layer is smaller than a refractive index of the second layer.

5. The display apparatus of claim 4, wherein a difference between the refractive index of the first layer and the refractive index of the second layer is 0.16 or more.

6. The display apparatus of claim 2, wherein the plurality of subpixels include a white subpixel, a red subpixel, a green subpixel and a blue subpixel,
wherein the radius of the second concave portion is in a range from 2.1 um to 2.5 um, inclusive, and
wherein a difference between a refractive index of the first layer and a refractive index of the second layer is 0.16 and the aspect ratio of the second concave portion is in a range from 0.9 to 1, inclusive.

7. The display apparatus of claim 2, wherein the plurality of subpixels include a white subpixel, a red subpixel, a green subpixel and a blue subpixel,
a difference between a refractive index of the first layer and a refractive index of the second layer is 0.2,
in the white subpixel, a second concave portion includes a radius in a range from 2 um to 2.5 um, inclusive, and the aspect ratio of the second concave portion in the white subpixel is in a range from 0.95 to 1.05, inclusive,
in the red subpixel, a second concave portion includes a radius in a range from 2 um to 2.7 um, inclusive, and the aspect ratio of the second concave portion in the red subpixel is in a range from 1 to 1.05, inclusive,
in the green subpixel, a second concave portion includes a radius in a range from 2 um to 2.55 um, inclusive, and the aspect ratio of the second concave portion in the green subpixel is in a range from 0.96 to 1.03, inclusive, and
in the blue subpixel, a second concave portion includes a radius in a range from 2 um to 2.5 um, inclusive, and the aspect ratio of the second concave portion in the blue subpixel is in a range from 0.95 to 1.05, inclusive.

8. The display apparatus of claim 2, wherein the plurality of subpixels include a light emitting layer on the light extraction portion,
light emitted from the light emitting layer, passing through the light extraction portion includes first extraction light which is incident on the second layer and is not reflected on a boundary surface between the first layer and the second layer and passes through the first layer, and second extraction light which is incident on the second layer and reflected at least once on the boundary surface between the first layer and the second layer and passes through the first layer.

9. The display apparatus of claim 2, wherein the plurality of subpixels include a light emission area overlapping the light extraction portion and having a light emitting element layer, and a non-light emission area adjacent to the light emission area,
the light emitting element layer includes:
a pixel electrode in the light emission area;
a light emitting layer on the pixel electrode and the non-light emission area; and
a reflective electrode disposed on the light emitting layer,
wherein the reflective portion is a portion of the reflective electrode.

10. The display apparatus of claim 1, wherein the plurality of subpixels include a light emission area and a non-light emission area adjacent to the light emission area, and
the pattern portion is disposed in a periphery of the non-light emission area.

11. The display apparatus of claim 10, wherein the first concave portion of the pattern portion is in the first layer and at least partially surrounds the light emission area in a form of a slit or a trench.

12. The display apparatus of claim 10, wherein the pattern portion is spaced apart from the light emission area.

13. The display apparatus of claim 1, wherein a width of the pattern portion decreases toward the substrate from the reflective portion.

14. The display apparatus of claim 9, wherein the pattern portion includes a bottom surface and an inclined surface connected to the bottom surface,
the bottom surface of the pattern portion is closer to the substrate than the pixel electrode, and
the inclined surface of the pattern portion surrounds the plurality of second concave portions.

15. The display apparatus of claim 14, wherein the inclined surface of the pattern portion forms an obtuse angle with the bottom surface.

16. The display apparatus of claim 14, further comprising a bank covering an edge of the pixel electrode,
wherein the second layer is in contact with the bottom surface while partially covering the inclined surface of the pattern portion, and
the bank is in contact with a portion of the bottom surface of the pattern portion while covering a part of the second layer that covers the inclined surface.

17. The display apparatus of claim 16, wherein each of the second layer and the bank on the bottom surface of the pattern portion is discontinuous.

18. The display apparatus of claim 9, wherein the second layer partially overlaps the light emission area, and
an upper surface of the second layer is flat.

19. A display apparatus comprising:
a substrate having a plurality of pixels, each pixel having a plurality of subpixels;
a pattern portion disposed on the substrate and having a concave structure between subpixels of the plurality of subpixels; and
a reflective portion on the pattern portion,
wherein the plurality of subpixels include an overcoat layer having a first layer on the substrate and a light extraction portion on the first layer and adjacent to the reflective portion, the first layer having a plurality of concave portions, and
a radius of a concave portion is related to a refractive index of the first layer.

20. The display apparatus of claim 19, wherein the radius (R_{BEST}) of the concave portion satisfies R_{BEST}=0.15 sin 4π(AR+0.05)+1.5n_{oc}+0.5m−0.59,
wherein ‘π’ is a circumferential rate, AR is an aspect ratio of the concave portion, ‘n_{oc}’ is a refractive index of the first layer, and ‘m’ is a variable value.

21. The display apparatus of claim 20, wherein the overcoat layer includes a second layer on the first layer,
an aspect ratio of the concave portion is a ratio of a vertical distance from a center of the concave portion in the second layer to the first layer with respect to a radius of the concave portion.

22. The display apparatus of claim 21, wherein the refractive index of the first layer is smaller than a refractive index of the second layer.

23. The display apparatus of claim 22, wherein a difference between the refractive index of the first layer and the refractive index of the second layer is 0.16 or more.

24. The display apparatus of claim 19, wherein a depth of the concave structure of the pattern portion is same as or greater than a depth of the concave portion.

25. The display apparatus of claim 19, wherein the plurality of subpixels includes a light emission area and a non-light emission area adjacent to the light emission area,
the light extraction portion overlaps the light emission area, and
the pattern portion is adjacent to the light extraction portion.

26. The display apparatus of claim 25, wherein the plurality of subpixels each includes a light emitting element layer,
the light emitting element layer includes:
a pixel electrode in the light emission area;
a light emitting layer on the pixel electrode and the non-light emission area; and
a reflective electrode disposed on the light emitting layer,
wherein the reflective portion is a portion of the reflective electrode.

27. The display apparatus of claim 21, wherein the pattern portion includes a bottom surface and an inclined surface connected to the bottom surface, and
the inclined surface of the pattern portion at least partially surrounds the plurality of concave portions.

28. The display apparatus of claim 27, wherein the second layer is in contact with a portion of the bottom surface of the pattern portion while partially covering the inclined surface of the pattern portion.

29. The display apparatus of claim 28, further comprising a bank covering an edge of the pixel electrode,
wherein the bank covers a portion of the second layer that covers the inclined surface of the pattern portion and is in contact with a portion of the bottom surface of the pattern portion.

30. The display apparatus of claim 29, wherein each of the second layer and the bank on the bottom surface of the pattern portion is discontinuous.

31. A display apparatus comprising:
a substrate having an emission area and a non-emission area adjacent to the emission area,
an overcoat layer in the emission area, the overcoat layer having a first layer and a light extraction portion on the first layer, the first layer having a plurality of concave portions; and
a reflective portion on the light extraction portion.

32. The display apparatus of claim 31, comprising a trench portion in the non-emission area, the trench portion at least partially surrounding the emission area.
